(19) United States
(12) Patent Application Publication
(10) Pub. No.: US 2011/0166045 A1
(43) Pub. Date: Jul. 7, 2011

(54) WAFER SCALE PLASMONICS-ACTIVE METALLIC NANOSTRUCTURES AND METHODS OF FABRICATING SAME

(76) Inventors: Anuj Dhawan, (US); Michael Gerhold, (US); Hsin-Neng Wang, Durham, NC (US); Veana Mara, Apex, NC (US); Tuan Vo-Dinh, Chapell Hill, NC (US); Yan Du, Oxford (GB)

(21) Appl. No.: 12/957,921

(22) Filed: Dec. 1, 2010

Related U.S. Application Data
(60) Provisional application No. 61/265,441, filed on Dec. 1, 2009.

(51) Int. Cl. C40B 60/12; G01N 21/55; G01N 21/41; H01L 21/20; H01L 29/66; B82Y 15/00; B82Y 40/00

(52) U.S. Cl. 506/39; 356/445; 356/128; 438/48; 257/467; 257/E21.09; 977/953; 257/E29.347

(57) ABSTRACT

Plasmonics-active nanostructure substrates—developed on a wafer scale in a reliable and reproducible manner such that these plasmonics-active nanostructures have nano-scale gaps (that include but are not limited to sub-10 nm gaps or sub-5 nm gaps) that provide the highest EM field enhancement between neighboring plasmonics-active metallic or metal-coated nanostructures. The plasmonics-active nanostructure substrates relate to environmental sensing based on SERS, SPR, LSPR, and plasmon enhanced fluorescence based sensing as well as for developing plasmonics enhanced devices such as solar cells, photodetectors, and light sources. Controllable development of sub-2 nm gaps between plasmonics-active nanostructures can also be achieved. Also, the size of the nano-scale gap regions can be tuned actively (e.g., by the application of voltage or current) to develop tunable sub-5 nm gaps between plasmonic nanostructures in a controllable manner.

### CROSS REFERENCE TO RELATED APPLICATION & PRIORITY CLAIM

This application claims priority to and the benefit of U.S. Provisional Application No. 61/265,441 filed on Dec. 1, 2009, which is incorporated herein by reference in its entirety as if fully set forth below.

### GOVERNMENT INTEREST

The presently disclosed subject matter was made with U.S. Government support by the Army Research Laboratory and the National Institutes of Health. Thus, the United States Government has certain rights in the disclosed subject matter. The embodiments described and claimed herein may be manufactured, used, sold and/or licensed by or for the United States Government without the payment of royalties thereon.

### TECHNICAL FIELD

The various embodiments of the present invention relate generally to plasmonic substrates, and more particularly, to the development of nano-scale gaps (that include but are not limited to sub-10 nm gaps or sub-5 nm gaps) between metallic nanostructures or metal-coated nanostructures on a large area such as wafer scale in a controllable manner, such that these substrates could be applied to different applications such as surface enhanced Raman scattering (SERS), surface plasmon resonance (SPR), plasmonics enhanced fluorescence and devices such as solar cells, photodetectors, light sources, etc.

### BACKGROUND

The enhancement of electromagnetic fields in the vicinity of metallic nanostructures and films is important for the development of sensitive plasmonics-based sensors (SERS, LSPR, and SPR based sensors) having improved limits of detection as well as plasmon-enhanced photovoltaics, photodetectors, and light sources such as lasers, laser diodes, LEDs, etc.

The enhancement of EM fields in the vicinity of metallic nanoparticles, metallic nanostructures on a substrates, as well as on the surface of thin metallic films can be explained by the phenomenon of localized surface plasmon resonance or thin film surface plasmon resonance. The shape and magnitude of the dip in the transmission or reflection spectra from these metallic structures depend on the enhanced scattering and absorption of light at specific wavelengths, which is related to the geometry of nanostructures or thin films illuminated by the incident light. The film based SPR could be based on excitation of surface plasmons in nanometer scale thin metallic films by radiation at specific wavelengths of light incident at a certain angle as, on one and two dimensional metallic gratings formed on the surface of the thin film, as well as on periodic nanoaperture arrays formed in the thin metallic films. The origin of plasmon resonances are collective oscillations of the conduction band electrons on the surface of the nanoparticles and films. Localized surface plasmons are excited when light is incident on metallic nanoparticles that have dimensions smaller than the wavelength of the incident light. At certain wavelengths, resonant multipolar modes are excited in the nanoparticles, leading to significant enhancement in absorbed and scattered light and strong increase in the electromagnetic fields in the vicinity of the particles. Localized surface plasmons can be detected as resonance peaks in the absorption and scattering spectra of the metallic nanoparticles. Excitation of localized surface plasmons are dependent on the shape and size of the nanoparticles, with higher fields observed in metallic nanoparticles having non-spherical geometries such as triangular or ellipsoidal nanoparticles as well as in the spacings between the metallic nanoparticles. Along with the LSPR effect, one can achieve high EM enhancement by producing “nano-antenna” effects occurring in the nano-scale spacings between multiple nanostructures. Nanostructures and thin films made up of noble metals, such as gold, silver, and copper, exhibit LSPR and SPR phenomena. The strength of the SERS effect depends surface plasmons, and as the excitation of LSPR or SPR is dependent on nanostructure geometry and the spacing between the nanostructures in the case of LSPR excitation, on the thickness of the metallic film and angle of incidence of the radiation, or on the periodicity of the metallic grating in the case of film based SPR excitation.

In recent years, surface-enhanced Raman scattering or SERS has become one of the most powerful spectroscopic tools employed for non-invasive and non-destructive detection of biomedical species as well as chemical and biological molecules. SERS spectra exhibit narrow spectral features characteristic of the detected analyte species which allows label-free and specific detection of these species in the presence of multiple other molecules in complex mixtures. Raman spectroscopy presents advantages over fluorescence spectroscopy, despite fluorescence cross-sections being higher than those of Raman scattering, due to the narrow spectral line widths of the Raman signals associated with the vibrational frequencies associated with bonds of molecules. Raman scattering can be described as an inelastic light scattering process in which a target sample on which light is incident absorbs one photon and emits another photon at the same time, the second photon being either at a lower frequency (i.e. Stokes scattering) or at a higher frequency (i.e. Anti-Stokes scattering) than the incident light frequency. While Raman scattering cross-sections are extremely small—typically between 10⁻³⁰ to 10⁻²⁵ cm² per molecule—thereby limiting its ability to detect the analyte species, Surface enhanced Raman scattering (SERS) increases the Raman scattering cross-section substantially enabling the application of this process for extremely sensitive and specific detection of the analytes. Reports on the large SERS enhancement factors of 10¹²-10¹⁵ have inspired the development of new sensing materials with the capability of single-molecule detection. The challenges lie in developing novel materials and substrates that not only achieve SERS enhancement factors—and achieve sub-5 nm and possibly sub-2 nm gaps between plasmonics-active nanostructures—that are as large as possible but can also be developed in a reliable and repeatable manner. The term plasmonics-active nanostructures refers to metallic nanostructures or nanostructure arrays whose dimensions and spacings are such that the plasmon resonance wavelengths associated with these nanostructures corresponds to the wavelengths of the radiation employed to interrogate them. Another challenge lies in the development of these substrates over a large area, such as an entire 4-inch, 6-inch, 8-inch, or 12-inch wafer and still captures the functionalities of large SERS enhancement factors and reproducibility of the SERS substrates.

In the case of SERS based sensors, the relationship between the SERS signals and the localized electric fields around the analytes being detected leads to improved sensitivity. Research efforts are currently devoted to maximize the SERS signals emanating from molecules located or near the nanoscale gaps between plasmonically active metallic nanostructures on the SERS substrates and to enhance the EM fields by developing metallic nanostructures with sharp corners, extremely small gaps between the metallic nanostructures creating SERS ‘hotspots’, and also to maximize the development of high density of such SERS hotspots. Most of the substrates employed in the initial research on SERS involved either formation of metallic electrodes roughened by oxidation-reduction cycles, metal island films, as well as over-coating of roughened surfaces by plasmonics active metal. Development of SERS substrates based on ordered metallic structures has been described in the past literature. The development of planar solid substrates covered with a monolayer of nanospheres that are coated with a thin layer of silver, thus producing a plasmonics-active 2D nanospheres arrays, has been reported. Another approach includes development of silver nanoparticle arrays, in which the silver nanoparticles are formed by electrodepositing silver onto porous anodic alumina substrates. Although, sub-5 nm gaps between the nanoparticles were obtained, the shapes and sizes of the different nanoparticles in the array seem to be different. In the SERS substrates such as the metal film on nanospheres substrates or an array of ordered nanotrianglar pillars developed by nanosphere lithography technique described, it is difficult to fabricate these structures reproducibly on the scale of an entire wafer. The substrates developed by electron beam lithography have large electron beam writing times as well as the limitation on the smallest features that could be formed in these substrates. Hence, electron beam lithography is unsuitable for large area SERS substrate fabrication. This process is also not conducive to fabrication of SERS substrates over a large area, specifically 6-inch wafers. Moreover, the smallest sizes of nano-scale gaps between metallic nano-structures using electron beam lithography and FIB are greater than 10 nm. Recent work to develop nanostructures on a large area substrate includes development of nanowells using soft lithography and of nanoprism arrays using nanoimprint lithography. The minimum feature sizes in the case of nanoprisms were approximately 100 nm and no sub-20 nm gap regions were present in these substrates. The nanowells seemed to be not of similar sizes and shapes over the substrate surface. Although SERS based substrates based on disordered metallic nanowires, ordered metallic nanowires, as well as metal-coated silicon or germanium oxide nanowires have been described in the past literature, the ability to reproducibly develop ordered metallic nanowires with controlled sizes, shapes, and sub-5 nm gaps between the nanowires has not been presented previously.

What is needed, therefore, are plasmonic nanostructure substrates—containing arrays of plasmonics-active nanostructures—and associated fabrication methods such that these substrates have nano-scale gaps (that include but are not limited to sub-10 nm gaps or sub-5 nm gaps) that provide the highest EM field enhancement between neighboring plasmonics-active metallic or metal-coated nanostructures, such that very large plasmonic enhancements of electromagnetic fields in between the nanostructures could be achieved. There is also a need for plasmonics-active nanostructures and associated manufacturing processes that enable the development of these plasmonic nanostructure substrates on a wafer-scale in a controllable and reliable manner. There is a need for such plasmonic substrates that can provide optical sensing devices and systems having improved enhancement in the electromagnetic fields around the nanostructures—therefore improved enhancement in SERS signals from molecules lying in the vicinity of these nanostructures and improvement in SPR and LSPR sensing based on these substrates—as well as enhancement in the performance of devices such as solar cells, photodetectors, and light sources (Lasers, laser diodes, and LEDs). It is to the provision of such plasmonic nanostructure substrates for environmental sensing and plasmon-enhanced solar cells, photodetectors, and light sources and methods for fabricating these plasmonic nanostructure substrates for use as environmental sensors and plasmon-enhanced solar cells, photodetectors, and light sources that the various embodiments of the present invention are directed.

### SUMMARY

Various embodiments of the present invention are directed to the fabrication of plasmonics-active nanostructures on a wafer scale in a reliable and reproducible manner such that these plasmonics-active nanostructures have nano-scale gaps (that include but are not limited to sub-10 nm gaps or sub-5 nm gaps) that provide the highest EM field enhancement between the nanostructures. For example embodiments of the present invention provide plasmonics-active one-dimensional (1D) and two-dimensional (2D) nanostructure arrays—developed on an a wafer scale such as a 4-inch, 6-inch wafer, 8-inch, or 12-inch wafers and having nano-scale gaps (that include but are not limited to sub-10 nm gaps or sub-5 nm gaps) that provide the highest EM field enhancement between the plasmonic nanostructures—in a controllable and reliable manner on the entire wafer surface. Also, according to some embodiments, controllable development of sub-2 nm gaps between plasmonics-active nanostructures can also be achieved.

Other advantageous features of the various embodiments of the present invention relate to environmental sensing—more specifically sensing of chemical, biological, and biomedical species based on surface enhanced Raman scattering (SERS), surface plasmon resonance (SPR), localized surface plasmon resonance (LSPR), and plasmon enhanced fluorescence based sensing—as well as for developing plasmonics enhanced devices such as solar cells, photodetectors, and light sources. Advantageously decreasing the size of the gaps between the plasmonics-active nanostructures in these plasmonic substrates leads to enhanced electromagnetic (EM) fields in these substrates thereby leading to enhanced sensing characteristics when these plasmonic substrates are employed as sensors. Also according to some embodiments of the present invention, the size of the nano-scale gap regions can be tuned actively (e.g., by the application of voltage or current) to develop tunable sub-5 nm gaps between plasmonic nanostructures in a controllable manner.

To describe certain embodiments and features of the present invention, the inventors may use certain positioning and location words and abbreviations herein. For example, sometimes the words couple and proximate (or variants thereof) are used. Use of these words is intended to encompass not only direct physical location or contact but also close proximity (i.e., indirect physical location or physical contact). As a result, certain features discussed herein can be coupled or proximate directly or indirectly. Regarding abbreviations, these are at times used herein and in the drawings. Used abbreviations include: LSPR to refer to localized surface plasmon resonance; SPR to refer to surface plasmon resonance; SERS to refer to surface-enhanced Raman scattering; EM to refer to electromagnetic; LED to refer to light emitting diode; ALD to refer to atomic layer deposition; MBE to refer to Molecular Beam Epitaxy, MOCVD to refer to metal organic chemical vapor deposition; FIB to refer to focused ion beam; PLD to refer to pulsed laser deposition; PED to refer to pulsed electron deposition, TEM to refer to transmission electron microscopy; MFON to refer to metal film on nanospheres; PNS to refer to plasmonic nanostructures; 1D to refer to one-dimensional; 2D to refer to two-dimensional; NSG to refer to nano-scale gaps; MNS to refer to metallic nanostructures and MCNS to refer to metal-coated nanostructures. Other abbreviations, such as periodic element abbreviations, may also be utilized herein.

Other aspects and features of embodiments of the present invention will become apparent to those of ordinary skill in the art, upon reviewing the following description of specific, exemplary embodiments of the present invention in conjunction with the accompanying figures.

### BRIEF DESCRIPTION OF THE DRAWINGS

The embodiments herein will be better understood from the following detailed description with reference to the drawings, in which:

FIG. 1 illustrates a cross-sectional view of a plasmonic substrate device;

FIG. 2 illustrates a cross-sectional view of another plasmonic substrate device;

FIGS. 3A-D show a TEM cross-sectional image;

FIGS. 4A-D show a SEM image of gold-coated nanowires;

FIG. 5 illustrates a cross-sectional view of a particular plasmonic substrate device;

FIG. 6 illustrates a cross-sectional view of another plasmonic substrate device;

FIG. 7 illustrates a cross-sectional view of another plasmonic substrate device;

FIG. 8 illustrates a cross-sectional view of another plasmonic substrate device;

FIG. 9 illustrates a cross-sectional view of another plasmonic substrate device;

FIG. 10 illustrates a cross-sectional view of another plasmonic substrate device;

FIG. 11 illustrates a cross-sectional view of another plasmonic substrate device;

FIGS. 12 A-B illustrate a cross-sectional view of another plasmonic substrate device;

FIGS. 13 A-B illustrate a cross-sectional view of another plasmonic substrate device;

FIG. 14 illustrates a cross-sectional view of another plasmonic substrate device;

FIGS. 15 A-C illustrate a cross-sectional view of another plasmonic substrate device;

FIGS. 16 A-B illustrate a cross-sectional view of another plasmonic substrate device;

FIG. 17 illustrates a cross-sectional view of another plasmonic substrate device;

FIGS. 18 A-B illustrate a cross-sectional view of another plasmonic substrate device;

FIGS. 19 A-B illustrate a cross-sectional view of how a plasmonic substrate device can be employed;

FIGS. 20 A-B illustrate a cross-sectional view of how a plasmonic substrate device can be employed in another implementation;

FIGS. 21A-B illustrate a cross-sectional view of how a plasmonic substrate device can be employed in another implementation;

FIGS. 22 A-B illustrate a cross-sectional view of how a plasmonic substrate device can be employed in another implementation;

FIGS. 23 A-B illustrate a cross-sectional view of how a plasmonic substrate device can be employed in another implementation;

FIGS. 24 A-B illustrate a cross-sectional view of how a plasmonic substrate device can be employed in another implementation;

FIGS. 25 A-B illustrate a cross-sectional view of how a plasmonic substrate device can be employed in another implementation;

FIGS. 26 A-C illustrate a cross-sectional view of how a plasmonic substrate device can be employed in another implementation;

FIGS. 27 A-C illustrate a cross-sectional view of how a plasmonic substrate device can be employed in another implementation;

FIGS. 28 A-C illustrate a cross-sectional view of how a plasmonic substrate device can be employed in another implementation;

FIG. 29 illustrates a cross-sectional view of how a plasmonic substrate device can be employed in another implementation; and

FIG. 30 illustrates a cross-sectional view of how a plasmonic substrate device can be employed in another implementation.

### DETAILED DESCRIPTION OF PREFERRED EMBODIMENTS

Referring now to the figures, wherein like reference numerals represent like parts throughout the several views, exemplary embodiments of the present invention will be described in detail. Throughout this description, various components may be identified having specific values or parameters, however, these items are provided as exemplary embodiments. Indeed, the exemplary embodiments do not limit the various aspects and concepts of the present invention as many comparable parameters, sizes, ranges, and/or values may be implemented.

The various embodiments provide many numerous advantageous features over conventional plasmonic substrates. The various embodiments of the present invention are directed to the fabrication of plasmonics-active nanostructures on a wafer scale such that these plasmonics-active nanostructures have nano-scale gaps (that include but are not limited to sub-10 nm gaps or sub-5 nm gaps) that provide the highest EM field enhancement between the nanostructures. Also, embodiments of the present invention provide plasmonic substrates fabricated in a reliable and reproducible manner on the scale of the entire wafer. For example, embodiments of the present invention provide plasmonics-active one-dimensional (1D) and two-dimensional (2D) nanostructure arrays—developed on an a wafer scale and having nano-scale gaps (that include but are not limited to sub-10 nm gaps or sub-5 nm gaps) that provide the highest EM field enhancement between the plasmonic nanostructures—in a controllable and reliable manner on the entire wafer surface. Also, according to some embodiments, controllable development of sub-2 nm gaps between plasmonics-active nanostructures can also be achieved.

Other advantageous features of the various embodiments of the present invention relate to environmental sensing—more specifically sensing of chemical, biological, and biomedical species based on surface enhanced Raman scattering (SERS), surface plasmon resonance (SPR), localized surface plasmon resonance (LSPR), and plasmon enhanced fluorescence based sensing—as well as for developing plasmonics enhanced devices such as solar cells, photodetectors, and light sources. Advantageously decreasing the size of the gaps between the plasmonics-active nanostructures in these plasmonic substrates leads to enhanced electromagnetic (EM) fields in these substrates thereby leading to enhanced sensing characteristics when these plasmonic substrates are employed as sensors. Also, according to some embodiments of the present invention, the size of the nano-scale gap regions can be tuned actively (e.g., by the application of voltage or current) to develop tunable sub-5 nm gaps between plasmonic nanostructures in a controllable manner.

Some embodiments of the present invention can also be used in transduction sensing methods and systems. For example, transduction of light incident on the plasmonic substrates can be achieved by absorption or scattering of the light by the plasmonic nanostructured materials present on the substrates. Such materials include, but are not limited to, metals or semiconductors. Transduction sensing methods and systems can be utilized for different environmental sensing applications. The deposited materials used according to the various embodiments of the present invention can have many different features. For example, these materials could be deposited as continuous films, nanostructures, or nanostructure-containing thin films.

Transduction of light incident on the plasmonic substrates can be obtained in numerous manners according to the various embodiments of the present invention. One exemplary manner includes excitation of surface plasmons—localized surface plasmon resonance (LSPR) as well as surface plasmon resonance (SPR) in the metallic and metal-coated nanostructures described in this invention. Other exemplary transduction manners include Surface Enhanced Raman Scattering (SERS) as well as excitations due to plasmon-enhanced fluorescence, and non-linear optical phenomena in the metallic/semiconductor nanostructures in the plasmonic substrates.

Still yet another exemplary manner includes interaction of light incident on the plasmonic substrate with a material on the surface of the substrate. Properties of materials disposed on a plasmonic substrate can be altered due to interaction when the material may go from one phase to another, the material may absorb light in certain spectral regions in the interaction region, or the interaction of light with the material on the plasmonic surface may form quasiparticles such as excitons, plasmons, magon, or other phenonoma that can manifest themselves as a peak or valleys in a corresponding transmission or reflection spectrum. Material applied to the plasmonic substrates can be a metal, alloy, or a semiconductor material, such as Vanadium oxide. The material may be in the form of a film or a nanostructure, and the material can alter or produce a change in the spectrum or intensity of light reflected from or transmitted through the material. As an example, this could be employed for temperature sensing if the material deposited on the surface of the plasmonic substrates has a change in optical properties as a function of temperature (as is the case of Vanadium oxide). As another example, this could be employed for gas sensing if the material deposited on the surface of the plasmonic substrates has a change in optical properties as a function of adsorption of a gas—as is the case of a hydrogen sensing by palladium thin film, palladium nanoparticle containing film, or palladium nanoparticles deposited on the plasmonic substrates described in the present invention.

Some embodiments of the present invention can also be used in applications including but not limited to plasmon-enhanced solar cells, photodetectors, and light sources (such as lasers, LEDs, laser diodes) as well as switches, modulators, and other applications where changes or alterations in light can provide pertinent data. As an example, the plasmonic enhancement of the radiation incident on the plasmonic substrates can lead to enhancement in efficiency of the solar cells due to plasmonically enhanced absorption or scattering, or light trapping in the solar cells using the different embodiments of the plasmonic substrates described in this invention.

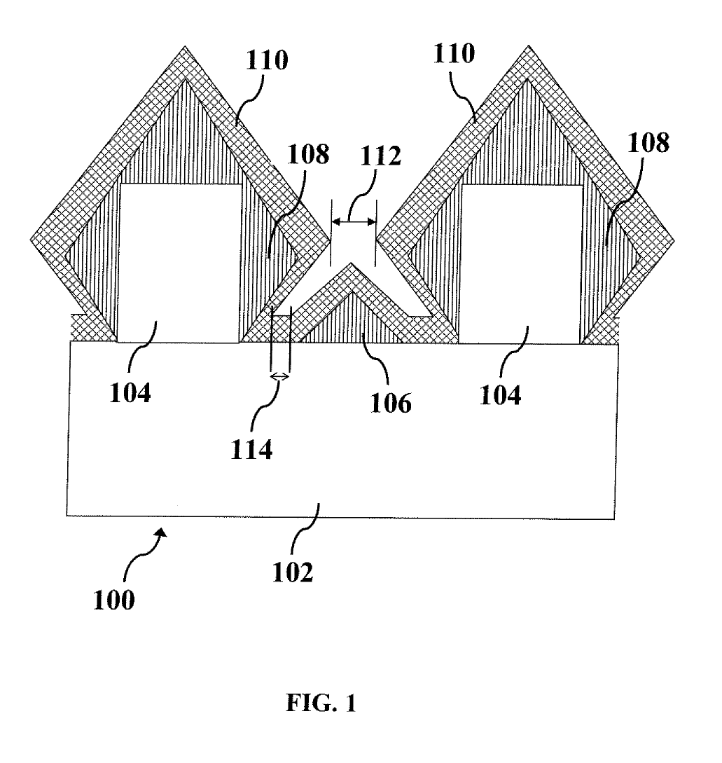

FIG. 1 illustrates a cross-sectional view of a diagram representing a plasmonic substrate device according to some embodiments of the present invention. Generally described, FIG. 1 illustrates a plasmonic substrate structure 100 that comprises several elements (or components) that form the entire substrate. The several elements making up the substrate structure 100 preferably have at least two dimensions less than 1 micron, preferably ranging from 20 to 500 nanometers. Preferably, the structures 104 have dimensions less than 1 micron (and will be referred to as nanostructures) with their width dimension ranging from 20 to 500 nanometers. The dimensions of the nanostructures in substrate 100 will be selected such that the nanostructures are plasmonics-active, i.e. plasmon resonances of the metallic nanostructures are excited for the given wavelength(s) of the incident radiation. One-dimensional and two-dimensional arrays of the nanostructures 104 are fabricated on the substrate 102 by following one or a combination of the following processes but not limited to deep UV lithography, focused ion beam (FIB) milling, electron beam lithography, TEM lithography, wet etching, and dry etching.

The various elements of the plasmonic substrate structure 100 can include varying types of components. For example, and as shown, plasmonic substrate structure 100 can generally include a substrate platform 102 on which the plasmonic substrate is developed, a first nanostructure 104 fabricated on the platform, and second nanostructure grown on the substrate 106, a third nanostructure 108 grown on the facets of nanostructures 104 that are perpendicular to the platform 102, and a film 110 coating the top surface of the plasmonic substrate 100.

The nanostructures 106 can be epitaxially grown or deposited on substrate 102 by employing growth methods that are not limited to such as ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes etc. As a specific example, In case the material of the platform substrate 102 is crystalline silicon, the nanostructures 106 can be epitaxially grown on the substrate 102 by employing growth ultra high vacuum rapid thermal chemical vapor deposition.

The lateral nanostructures 108 can be epitaxially grown or deposited on certain facets of nanostructures 104 by employing growth methods that are not limited to such as ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes etc. As a specific example, in case the material of the platform substrate 102 is crystalline silicon and the nanostructures 104 are also developed from the silicon substrate, the lateral nanostructures 108 can be epitaxially grown on certain facets of nanostructures 104 by employing growth ultra high vacuum rapid thermal chemical vapor deposition. By controlling the time and rate of the growth of the lateral nanostructures 108 and 106 as well as the thickness of the plasmonic layer 110, one can control the spacings 112 and 114—between neighboring plasmonic layer-coated lateral nanostructures 108, and between the plasmonic-layer coated nanostructures 106 and 108 respectively. Hence, one can achieve nano-scale gaps 112 and 114 (that could be smaller than 10 nm and if desirable even smaller than 5 nm) between neighboring plasmonics-active nanostructures that provide the highest enhancement of EM fields in the vicinity of these nanostructures.

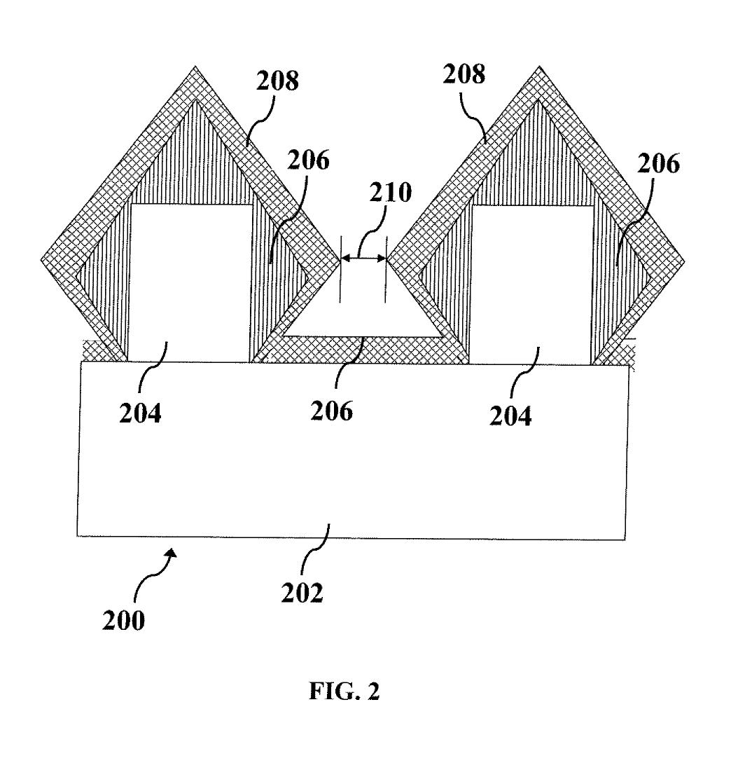

FIG. 2 illustrates a cross-sectional view of a diagram representing a plasmonic substrate device according to some embodiments of the present invention. Generally described, FIG. 2 illustrates a plasmonic substrate structure 200 that comprises several elements (or components) that form the entire substrate. The several elements making up the substrate structure 200 preferably have dimensions less than 1 micron, preferably ranging from 20 to 500 nanometers. The dimensions of the nanostructures in substrate 200 will be selected such that the nanostructures are plasmonics-active, i.e. plasmon resonances of the metallic nanostructures are excited for the given wavelength(s) of the incident radiation. One-dimensional and two-dimensional arrays of the nanostructures 204 are fabricated on the substrate 202 by following one or a combination of the following processes but not limited to deep UV lithography, focused ion beam (FIB) milling, electron beam lithography, TEM lithography, wet etching, and dry etching. Preferably, the structures 204 have at least two dimensions less than 1 micron (and will be referred to as nanostructures) with their width dimension ranging from 20 to 500 nanometers.

The various elements of the plasmonic substrate structure 200 can include varying types of components. For example, and as shown, plasmonic substrate structure 200 can generally include a substrate platform 202 on which the plasmonic substrate is developed, a first nanostructure 204 fabricated on the platform, and second nanostructure 206 grown on the facets of nanostructures 204 that are perpendicular to the platform 202, and a film 208 coating the top surface of the plasmonic substrate 200.

The lateral nanostructures 206 can be epitaxially grown or deposited on certain facets of nanostructures 204 by employing growth methods that are not limited to such as ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes etc. As a specific example, In case the material of the platform substrate 202 is silicon-di-oxide and the nanostructures 204 are developed from the crystalline silicon layer (silicon on insulator or SOI) on top of the substrate 202, the lateral nanostructures 206 can be epitaxially grown on certain facets of nanostructures 204 by employing growth ultra high vacuum rapid thermal chemical vapor deposition. By controlling the time and rate of the growth of the lateral nanostructures 206 as well as the thickness of the plasmonic layer 208, one can control the spacing 210 between neighboring plasmonic layer-coated lateral nanostructures 206. Hence, one can achieve nano-scale gaps 210 (that could be smaller than 10 nm and if desirable even smaller than 5 nm) between neighboring plasmonics-active nanostructures that provide the highest enhancement of EM fields in the vicinity of these nano structures.

The films 110, 208 can take on a variety of shapes and include a variety of materials. Exemplary materials can include metallic or semiconductive materials that exhibit plasmonic properties. Specific material examples include but are not limited to Au, Ag, Cu, Pt, Pd, Ti, Cr, Zn, Al, Ni, Fe, V, W, Ru, Hf Zr, Ta, semiconducting materials, combinations of these materials, or a combination of these materials with metal oxides.

The film 110 can be deposited onto the substrate regions 102, 106, and 108 and the film 208 onto the substrate regions 202 and 206 to form plasmonic nanostructure substrates 100 and 200 respectively. For example, metal deposition can be accomplished by atomic layer deposition, E-Beam deposition, thermal evaporation, sputter deposition, pulsed laser deposition, pulsed electron deposition, chemical vapor deposition, molecular beam epitaxy (MBE), metal organic chemical vapor deposition (MOCVD), and hydrothermal processes etc. The metallic and semiconducting thin films can be formed by employing one or more deposition or film/nanostructure growth mechanisms such as E-Beam deposition, thermal evaporation, pulsed laser deposition, pulsed electron deposition, chemical vapor deposition, molecular beam epitaxy (MBE), metal organic chemical vapor deposition (MOCVD), atomic layer deposition, and hydrothermal processes. Semiconducting thin films containing metallic nanoparticles can also be formed by one or more of pulsed laser deposition, pulsed electron deposition, chemical vapor deposition, molecular beam epitaxy (MBE), metal organic chemical vapor deposition (MOCVD), and atomic layer deposition.

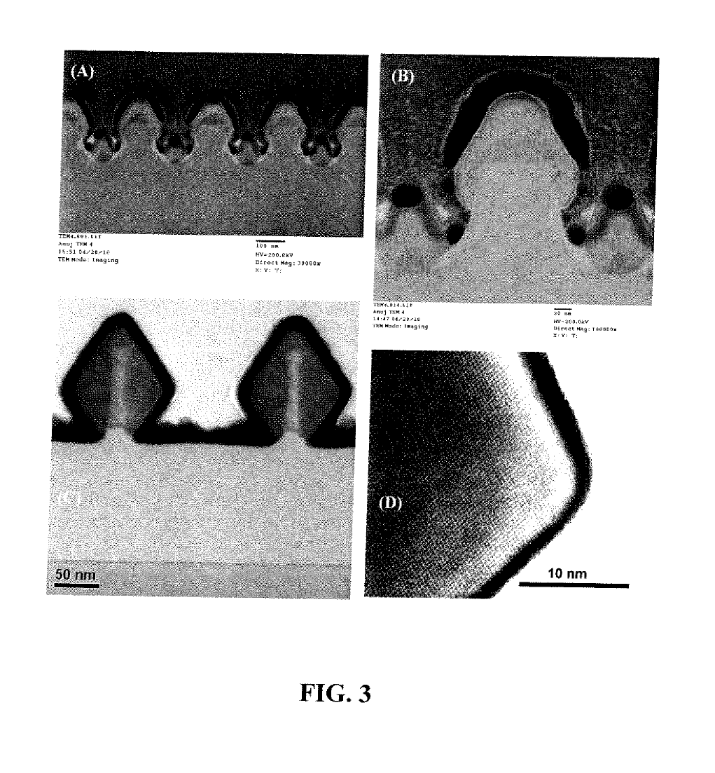

FIG. 3A and FIG. 3B show TEM cross-section image showing small triangular sections formed in between the gold-coated diamond shaped nanowires. To develop the plasmonic diamond shaped nanowire structures, silicon germanium epitaxial films were grown on the silicon nanowires (that were fabricated using deep UV lithography) using the ultra high vacuum rapid thermal chemical vapor deposition process and then over-coated with a layer of plasmonics-active metal such as silver or gold. The controlled epitaxial growth led to unique diamond-shaped structures of the silicon germanium nanowires and enabled the gap between the nanowires to be precisely controlled. During epitaxial growth of silicon germanium, at the growth temperature of 550° C., silicon germanium growth on the (111) facet was dominantly observed. Between two parallel diamond shaped nanowires, there are small triangular sections and the nanoscale gap between the gold film on the diamond-shaped nanowires and these triangular sections is less than 10 nm. FIG. 3C shows TEM cross-section image showing atomic layer deposition (ALD) of platinum (in black) on the diamond-shaped germanium nanowires formed on SOI wafers (grey). In FIG. 3C, one does not observe the triangular sections in between the diamond-shaped nanowires as there is no silicon layer present at the bottom of the silicon nanowires developed on top of the silica layer of the SOI wafers. FIG. 3D shows a high-resolution TEM image of a diamond shaped nanowire indicating the crystal planes of a epitaxial silicon germanium nanowire that is over-coated with a conformal layer of platinum deposited by employing atomic layer deposition.

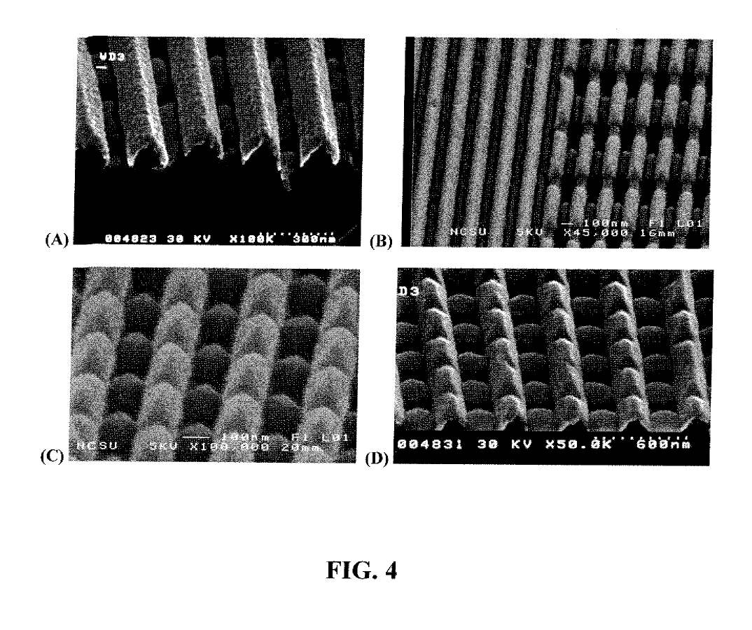

FIG. 4A shows an SEM image of gold-coated one-dimensional diamond-shaped germanium nanowires gold-coated nanowires with small triangular nanostructures in between the diamond-shaped regions. FIG. 4B shows an SEM image of gold-coated two-dimensional diamond-shaped germanium nanowires gold-coated nanowires. To fabricate two-dimensional nanowire arrays, silicon nanowires developed by deep UV lithography were periodically covered by SiO₂ using a second masking process and deep UV lithography to create SiO₂ lines running in the direction perpendicular to the silicon nanowires. When the silicon germanium growth was carried out on this structure, growth of silicon germanium to form the diamond-shaped structure took place only in regions where silicon was present as the SiO₂ layer prevented the formation of diamond-shaped structures. The two-dimensional nanowire arrays were over-coated with a layer of plasmonics-active metal layer.

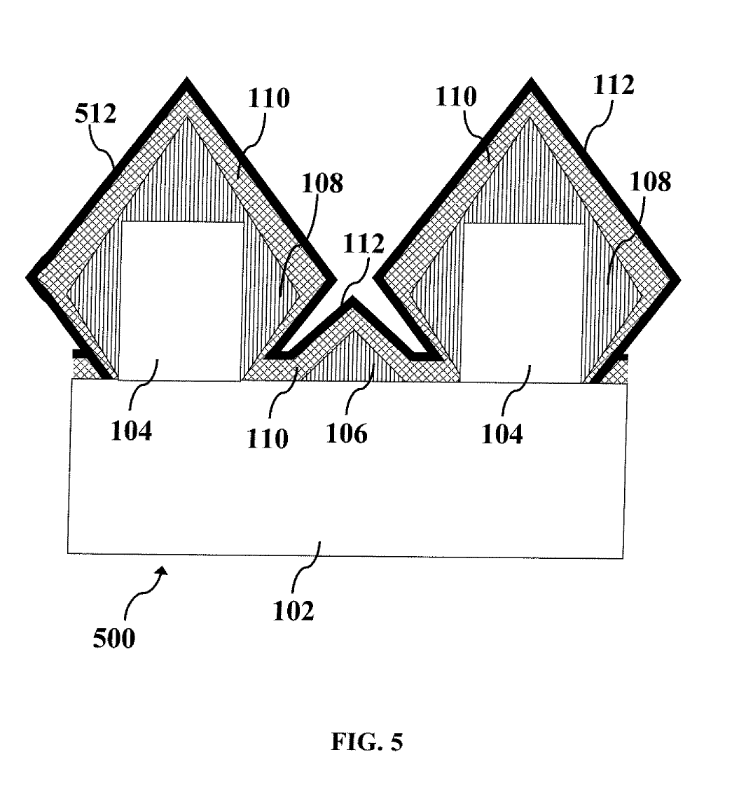

FIG. 5 illustrates a cross-sectional view of a diagram representing a plasmonic substrate structure 100 that is over-coated with a thin film layer 512. The thin film material may be in the form of a film or a nanostructure-containing film, and the material can alter or produce a change in the spectrum or intensity of light reflected from or transmitted through the film when the environmental conditions around the thin film are changed. As an example, this could be employed for temperature sensing if the material deposited on the plasmonic structures in substrate 100 has a change in optical properties as a function of temperature (as is the case of Vanadium oxide). As another example, this could be employed for gas sensing if the material deposited on the surface of the plasmonic substrates has a change in optical properties as a function of adsorption of a gas—as is the case of a hydrogen sensing by palladium thin film, palladium nanoparticle containing film, or palladium nanoparticles deposited on the plasmonic substrates described in the present invention. As a specific example, the thin film layer can be palladium or platinum thin film, having a thickness varying between 0.5 nanometers and 3 nanometers, deposited in a conformal manner by employing atomic layer deposition such that the structure 500 can be employed for hydrogen sensing applications. In this example, the thickness of the thin film layer 512 has to be substantially small (less than 5 nm) such that the effects of the plasmonic enhancement of EM fields due to the underlying plasmonic substrate 100 are not reduced.

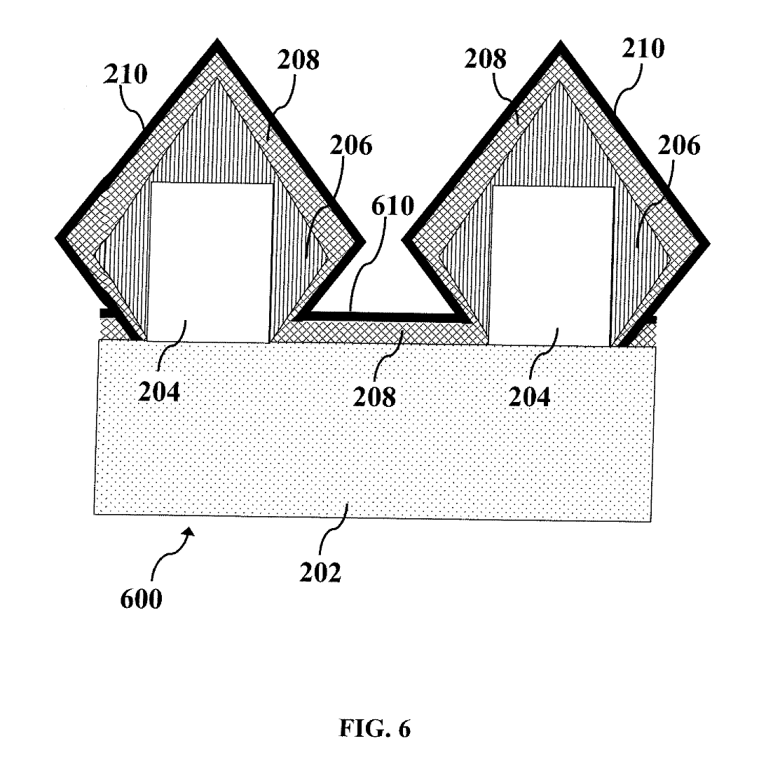

FIG. 6 illustrates a cross-sectional view of a diagram representing a plasmonic substrate structure 200 that is over-coated with a thin film layer 610. The thin film material may be in the form of a film or a nanostructure-containing film, and the material can alter or produce a change in the spectrum or intensity of light reflected from or transmitted through the film when the environmental conditions around the thin film are changed. As an example, this could be employed for temperature sensing if the material deposited on the plasmonic structures in substrate 200 has a change in optical properties as a function of temperature (as is the case of Vanadium oxide). As another example, this could be employed for gas sensing if the material deposited on the surface of the plasmonic substrates has a change in optical properties as a function of adsorption of a gas—as is the case of a hydrogen sensing by palladium thin film, palladium nanoparticle containing film, or palladium nanoparticles deposited on the plasmonic substrates described in the present invention. As a specific example, the thin film layer can be palladium or platinum thin film, having a thickness varying between 0.5 nanometers and 3 nanometers, deposited in a conformal manner by employing atomic layer deposition such that the structure 600 can be employed for hydrogen sensing applications. In this example, the thickness of the thin film layer 610 has to be substantially small (less than 5 nm) such that the effects of the plasmonic enhancement of EM fields due to the underlying plasmonic substrate 200 are not reduced.

The thin films 512, 610 can include a variety of materials. Exemplary materials can include metallic, dielectric, or semiconductive materials. Specific material examples include but are not limited to Au, Ag, Cu, Pt, Pd, Ti, Cr, Zn, Al, Ni, Fe, V, W, Ru, Hf Zr, Ta, metal oxides, other dielectric and semiconductor materials, or combinations of these materials. The combination of these materials could be achieved as a multilayer stack (i.e. multiple layers of the different materials described above forming a composite material) or with a nano-composite material (with nanoparticles or nano-crystals of the different materials embedded in other materials).

The films 512, 610 can be deposited onto the substrates 100 and 200 respectively by employing several deposition methods. Metallic and semiconducting nano-composite materials can be deposited or grown by one or more of atomic layer deposition, pulsed laser deposition, pulsed electron deposition, chemical vapor deposition, molecular beam epitaxy (MBE), metal organic chemical vapor deposition (MOCVD), and. The metallic and semiconducting thin films can be formed by employing one or more deposition or film/nanostructure growth mechanisms such as atomic layer deposition, E-Beam deposition, thermal evaporation, pulsed laser deposition, pulsed electron deposition, chemical vapor deposition, molecular beam epitaxy (MBE), metal organic chemical vapor deposition (MOCVD), and hydrothermal processes.

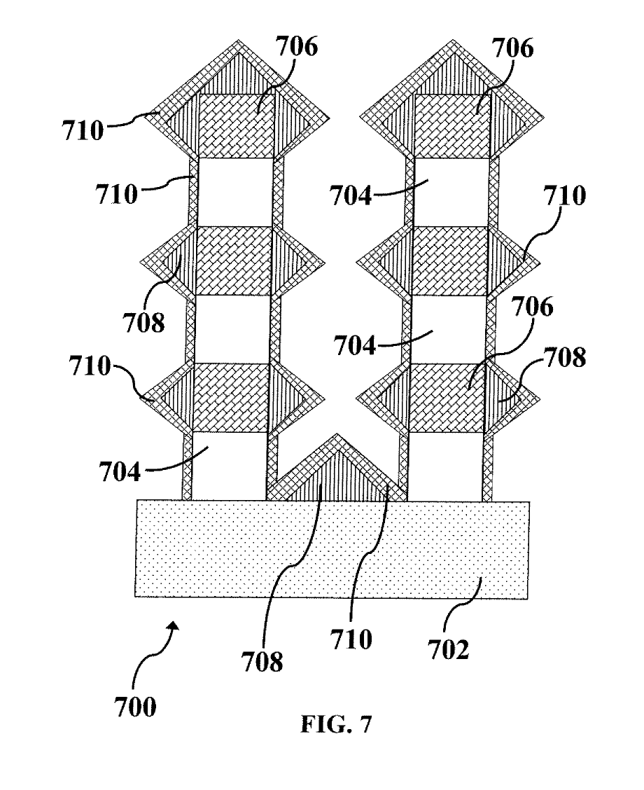

FIG. 7 illustrates a cross-sectional view of a diagram representing a plasmonic substrate device according to some embodiments of the present invention. Generally described, FIG. 7 illustrates a plasmonic substrate structure 700 that comprises several elements (or components) that form the entire substrate. The several elements making up the substrate structure 700 preferably have dimensions less than 1 micron, preferably ranging from 20 to 500 nanometers.

Preferably, the structure regions 704 and 706 have dimensions less than 1 micron (and will be referred to as nanostructures) with their width dimension ranging from 20 to 500 nanometers.

The dimensions of the nanostructures in substrate device 700 will be selected such that the nanostructures are plasmonics-active, i.e. plasmon resonances of the metallic nanostructures are excited for the given wavelength(s) of the incident radiation. One-dimensional and two-dimensional arrays of nanostructures of multiple alternating layers of materials 704 and 706 are fabricated by employing one or a combination of the following processes but not limited to deep UV lithography, focused ion beam (FIB) milling, electron beam lithography, TEM lithography, wet or dry etching methods, and thin film deposition techniques.

The various elements of the plasmonic substrate structure 700 can include varying types of components. For example, and as shown, plasmonic substrate structure 700 can generally include a substrate platform 702 on which the plasmonic substrate is developed, a first nanostructure—a one- or two-dimensional array of nanostructures containing a multilayer stack of regions 704 and 706, with regions 704 and 706 forming alternating layers of the stack—fabricated on the platform, and second nanostructure 708 grown on the substrate, a third nanostructure 710 grown on the facets of nanostructure regions 706 that are perpendicular to the platform 702, and a film 712 coating the top surface of the plasmonic substrate 700.

The nanostructures 708 can be epitaxially grown or deposited on the substrate region 702 by employing growth methods that are not limited to such as ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes etc. As a specific example, In case the material of the platform substrate 702 is crystalline silicon, the nanostructures 708 can be epitaxially grown on the substrate 702 by employing growth ultra high vacuum rapid thermal chemical vapor deposition.

The lateral nanostructures 710 can be epitaxially grown or deposited on certain facets of nanostructure regions 706 by employing growth methods such as—but not limited to—ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes etc. As a specific example, in case the material of the platform substrate 702 is crystalline silicon and the nanostructures—with alternating regions 704 and 706—are also developed such that the region 706 is made up of crystalline silicon, the lateral nanostructures 710 can be epitaxially grown on certain facets of nanostructures 706 by employing growth ultra high vacuum rapid thermal chemical vapor deposition. By controlling the time and rate of the growth of the lateral nanostructures 710 as well as the thickness of the plasmonic layer 712, one can control the spacings between neighboring plasmonic layer-coated nanostructures in the plasmonic substrate 700. Hence, one can achieve nano-scale gaps (that could be smaller than 10 nm and if desirable even smaller than 5 nm) between neighboring plasmonics-active nanostructures that provide the highest enhancement of EM fields in the vicinity of these nanostructures.

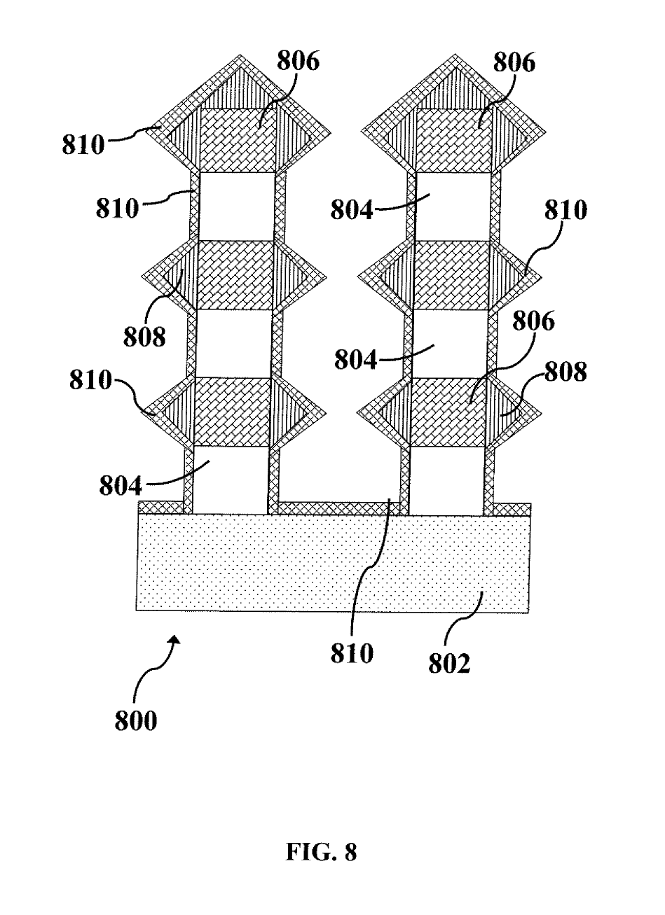

FIG. 8 illustrates a cross-sectional view of a diagram representing a plasmonic substrate device according to some embodiments of the present invention. Generally described, FIG. 8 illustrates a plasmonic substrate structure 800 that comprises several elements (or components) that form the entire substrate. The several elements making up the substrate structure 800 preferably have dimensions less than 1 micron, preferably ranging from 20 to 500 nanometers. Preferably, the structure regions 804 and 806 have dimensions less than 1 micron (and will be referred to as nanostructures) with their width dimension ranging from 20 to 500 nanometers. The dimensions of the nanostructures in substrate device 800 will be selected such that the nanostructures are plasmonics-active, i.e. plasmon resonances of the metallic nanostructures are excited for the given wavelength(s) of the incident radiation. One-dimensional and two-dimensional arrays of nanostructures of multiple alternating layers of materials 804 and 806 are fabricated by employing one or a combination of the following processes but not limited to deep UV lithography, focused ion beam (FIB) milling, electron beam lithography, TEM lithography, wet or dry etching methods, and thin film deposition techniques.

The various elements of the plasmonic substrate structure 800 can include varying types of components. For example, and as shown, plasmonic substrate structure 800 can generally include a substrate platform 802 on which the plasmonic substrate is developed, a first nanostructure—a one- or two-dimensional array of nanostructures containing a multilayer stack of regions 804 and 806, with regions 804 and 806 forming alternating layers of the stack—fabricated on the platform, and second nanostructure 808 grown on the facets of nanostructure regions 806 that are perpendicular to the platform 802, and a film 810 coating the top surface of the plasmonic substrate 800.

The lateral nanostructures 808 can be epitaxially grown or deposited on certain facets of nanostructure regions 806 by employing growth methods such as—but not limited to—ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes etc. As a specific example, in case the material of the platform substrate 802 is crystalline silicon and the nanostructures—with alternating regions 804 and 806—are also developed such that the region 806 is made up of crystalline silicon, the lateral nanostructures 808 can be epitaxially grown on certain facets of nanostructures 806 by employing growth ultra high vacuum rapid thermal chemical vapor deposition. By controlling the time and rate of the growth of the lateral nanostructures 808 as well as the thickness of the plasmonic layer 810, one can control the spacings between neighboring plasmonic layer-coated nanostructures in the plasmonic substrate 800. Hence, one can achieve nano-scale gaps (that could be smaller than 10 nm and if desirable even smaller than 5 nm) between neighboring plasmonics-active nanostructures that provide the highest enhancement of EM fields in the vicinity of these nanostructures.

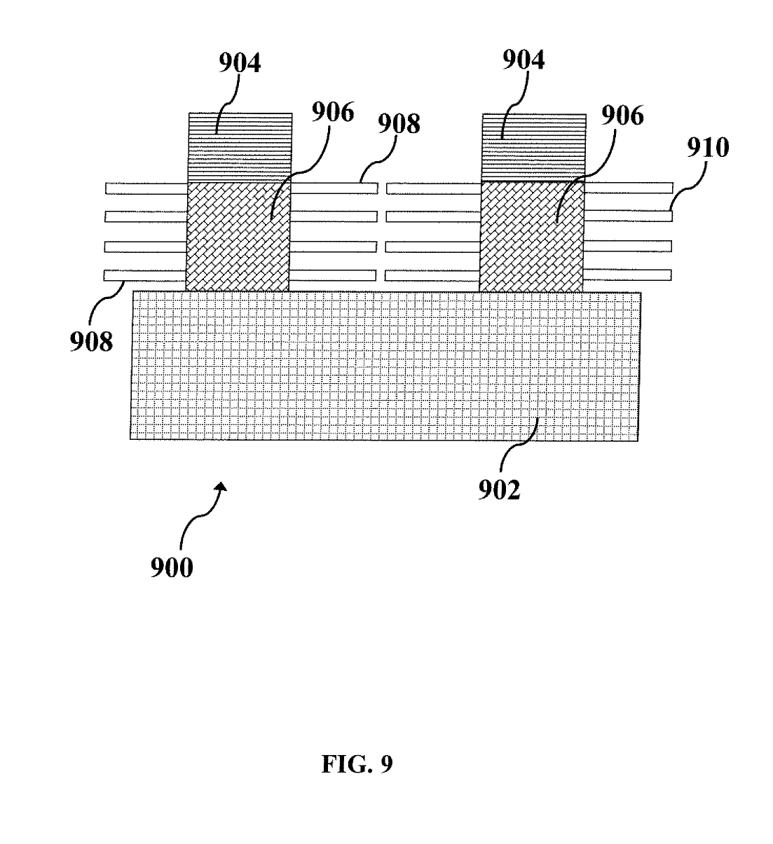

FIG. 9 illustrates a cross-sectional view of a diagram representing a plasmonic substrate device according to some embodiments of the present invention. The dimensions of the nanostructures in substrate 900 will be selected such that the nanostructures are plasmonics-active, i.e. plasmon resonances of the metallic nanostructures are excited for the given wavelength(s) of the incident radiation. One-dimensional and two-dimensional arrays of the nanostructures—with the nanostructure region 904 on top of region 906—are fabricated on the substrate 902 by following one or a combination of the following processes but not limited to deep UV lithography, focused ion beam (FIB) milling, electron beam lithography, TEM lithography, wet etching, and dry etching.

The various elements of the plasmonic substrate structure 900 can include varying types of components. For example, and as shown, plasmonic substrate structure 900 can generally include a substrate platform 902 on which the plasmonic substrate is developed, a first plasmonics-active nanostructure 908 that grows laterally from the surface of nanostructure region 906 that are perpendicular to the platform 902, and a second plasmonics-active nanostructure 910 that grows laterally from the surface of nanostructure region 906 that are perpendicular to the platform 902. Region 904 on top of the region 906 ensures there is no growth of nanostructures 908 and 910 in the direction perpendicular to the platform 902.

The nanostructures 908, 910 can be epitaxially grown by employing growth methods such as, that are not limited to, ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes etc.

The nanostructures 908, 910 can take on a variety of shapes and include a variety of materials. Exemplary materials can include metallic or semiconductive materials that exhibit plasmonic properties. Specific material examples include but are not limited to Au, Ag, Cu, Pt, Pd, Ti, Cr, Zn, Al, Ni, Fe, V, W, Ru, Hf Zr, Ta, semiconducting materials, combinations of these materials, or a combination of these materials with metal oxides.

Different possibilities of nanostructures 908 and 910 are possible that include the ends of 908 and 910 either facing each other or the nanostructures growing in opposite directions in a manner that they run parallel to each other. Hence, one can achieve nano-scale gaps between the ends of nanostructures 908 and 910—that could be smaller than 10 nm and if desirable even smaller than 5 nm—that provide the highest enhancement of EM fields in the vicinity of these nano structures.

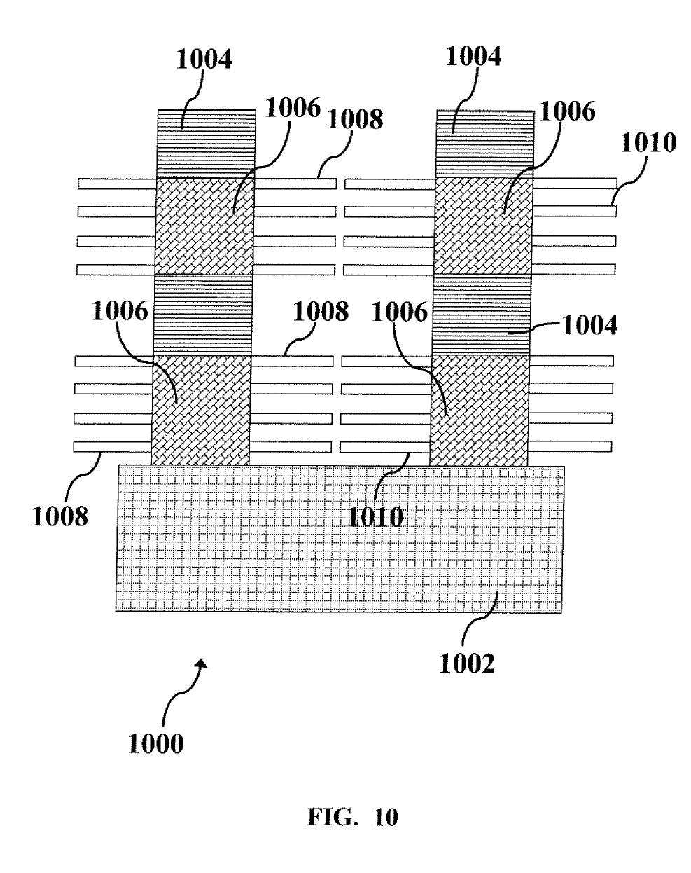

FIG. 10 illustrates a cross-sectional view of a diagram representing a plasmonic substrate device according to some embodiments of the present invention. The dimensions of the nanostructures in substrate 1000 will be selected such that the nanostructures are plasmonics-active, i.e. plasmon resonances of the metallic nanostructures are excited for the given wavelength(s) of the incident radiation. One-dimensional and two-dimensional arrays of the nanostructures—with multiple alternating nanostructure regions 1004 and 1006—are fabricated on the substrate 1002 by following one or a combination of the following processes but not limited to deep UV lithography, focused ion beam (FIB) milling, electron beam lithography, TEM lithography, wet etching, and dry etching.

The various elements of the plasmonic substrate structure 1000 can include varying types of components. For example, and as shown, plasmonic substrate structure 1000 can generally include a substrate platform 1002 on which the plasmonic substrate is developed, a first plasmonics-active nanostructure 1008 that grows laterally from the surface of nanostructure region 1006 that are perpendicular to the platform 1002, and a second nanostructure plasmonics-active 1010 that grows laterally from the surface of nanostructure region 1006 that are perpendicular to the platform 1002. The presence of regions 1004 ensure there is no growth of nanostructures 1008 and 1010 in these regions.

The nanostructures 1008, 1010 can be epitaxially grown by employing growth methods such as, that are not limited to, ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes etc.

The nanostructures 1008, 1010 can take on a variety of shapes and include a variety of materials. Exemplary materials can include metallic or semiconductive materials that exhibit plasmonic properties. Specific material examples include but are not limited to Au, Ag, Cu, Pt, Pd, Ti, Cr, Zn, Al, Ni, Fe, V, W, Ru, Hf Zr, Ta, semiconducting materials, combinations of these materials, or a combination of these materials with metal oxides.

Different possibilities of nanostructures 1008 and 1010 are possible that include the ends of 1008 and 1010 either facing each other or the nanostructures growing in opposite directions in a manner that they run parallel to each other. Hence, one can achieve nano-scale gaps between the ends of nanostructures 1008 and 1010—that could be smaller than 10 nm and if desirable even smaller than 5 nm—that provide the highest enhancement of EM fields in the vicinity of these nanostructures.

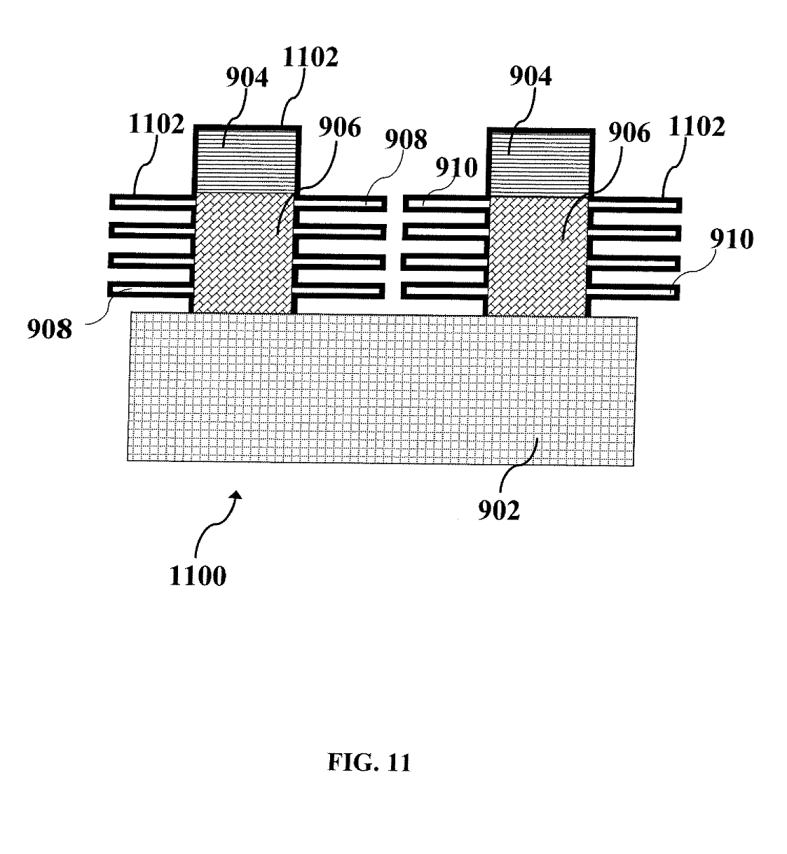

FIG. 11 illustrates a cross-sectional view of a diagram representing a plasmonic substrate structure 900 that is over-coated with a thin film layer 1102. The layer 1102 may be composed of thin films of metallic materials, semi-conducting materials or alloys or combinations of these materials, as well as thin films containing nanostructures of these materials. These materials can be selected such that they exhibit change of optical properties (such as refractive index, optical transmission, polarization) upon increasing temperature around these films and nanostructures or other environmental changes as discussed herein. Exemplary materials can include metallic, dielectric, or semiconductive materials. Specific material examples include but are not limited to Au, Ag, Cu, Pt, Pd, Ti, Cr, Zn, Al, Ni, Fe, V, W, Ru, Hf Zr, Ta, metal oxides, other dielectric and semiconductor materials, or combinations of these materials. The combination of these materials could be achieved as a multilayer stack (i.e. multiple layers of the different materials described above forming a composite material) or with a nano-composite material (with nanoparticles or nano-crystals of the different materials embedded in other materials).

As an example, this thin film layer 1102 could be employed for gas sensing if the material deposited on the surface of the plasmonic substrates 900 has a change in optical properties as a function of adsorption of a gas—as is the case of a hydrogen sensing by palladium thin film, palladium nanoparticle containing film, or palladium nanoparticles deposited on the plasmonic substrates described in the present invention. As a specific example, the thin film layer can be palladium or platinum thin film, having a thickness varying between 0.5 nanometers and 3 nanometers, deposited in a conformal manner by employing atomic layer deposition such that the structure 900 can be employed for hydrogen sensing applications. In this example, the thickness of the thin film layer 1102 has to be substantially small (less than 5 nm) such that the effects of the plasmonic enhancement of EM fields due to the underlying plasmonic substrate 900 are not reduced.

The film 1102 can be deposited onto the substrate 900 respectively by employing several deposition methods. Metallic and semiconducting nano-composite materials can be deposited or grown by one or more of atomic layer deposition, pulsed laser deposition, pulsed electron deposition, chemical vapor deposition, molecular beam epitaxy (MBE), metal organic chemical vapor deposition (MOCVD), and. The metallic and semiconducting thin films can be formed by employing one or more deposition or film/nanostructure growth mechanisms such as atomic layer deposition, E-Beam deposition, thermal evaporation, pulsed laser deposition, pulsed electron deposition, chemical vapor deposition, molecular beam epitaxy (MBE), metal organic chemical vapor deposition (MOCVD), and hydrothermal processes.

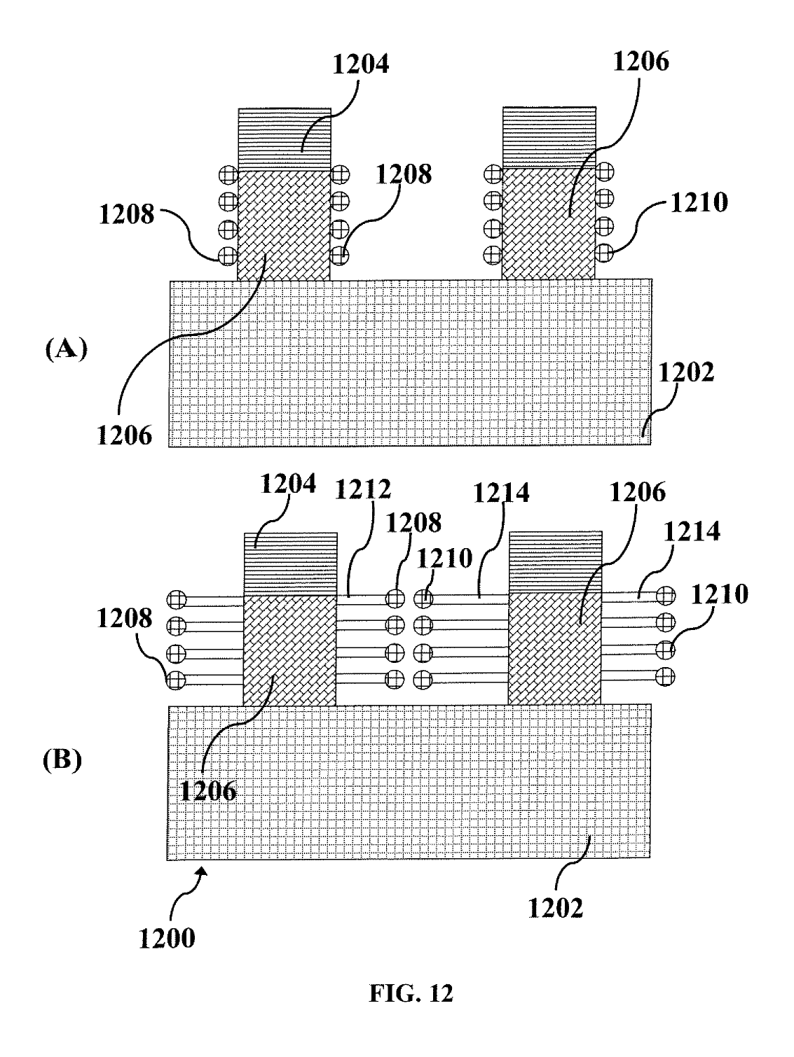

FIG. 12 illustrates a cross-sectional view of a diagram representing a plasmonic device according to some embodiments of the present invention. One-dimensional and two-dimensional arrays of the nanostructures—with the nanostructure region 1204 on top of region 1206—are fabricated on the substrate 1202 by following one or a combination of the following processes but not limited to deep UV lithography, focused ion beam (FIB) milling, electron beam lithography, TEM lithography, wet etching, and dry etching.

The various elements of the plasmonic substrate structure 1200 can include varying types of components. For example, and as shown, plasmonic substrate structure 1200 can generally include a substrate platform 1202 on which the plasmonic substrate is developed, a first nanoparticle 1208 that is deposited, attached, or formed the surface of nanostructure region 1206 that are perpendicular to the platform 1202, and a second nanoparticle 1210 that is deposited, attached, or formed the surface of nanostructure region 1206 that are perpendicular to the platform 1202. Region 1204 on top of the region 1206 is selected or modified such that ensures there is no deposition, formation, or attachment of nanoparticles 1208 or 1210 on the surface of region 1204 (See FIG. 12A). The nanoparticles 1208 and 1210 are plasmonics-active and also act as catalysts for the growth of nanowires 1212 and 1214 laterally on regions 1206. The growth of the nanowires brings the plasmonics-active nanoparticles 1208 and 1210 closer to each other and this can enable the nano-scale gap between the plasmonic nanoparticles 1208 and 1210 to be precisely controlled. Hence, one can achieve nano-scale gaps between the ends of nanoparticles 1208 and 1210—that could be smaller than 10 nm and if desirable even smaller than 5 nm—that provide the highest enhancement of EM fields in the vicinity of these nanostructures.

The nanowires 1212, 1214 can be epitaxially grown by employing growth methods such as, that are not limited to, ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes etc.

The nanoparticles 1208, 1210 can take on a variety of shapes and include a variety of materials. Exemplary materials can include metallic or semiconductive materials that exhibit plasmonic properties. Specific material examples include but are not limited to Au, Ag, Cu, Pt, Pd, Ti, Cr, Zn, Al, Ni, Fe, V, W, Ru, Hf Zr, Ta, semiconducting materials, combinations of these materials, or a combination of these materials with metal oxides.

The nanoparticles can be deposited, grown, attached, or formed on the regions 1206 by employing methods such as, that are not limited to, atomic layer deposition, electron beam deposition, sputter deposition, ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes, and chemical synthesis in combination with thermal annealing.

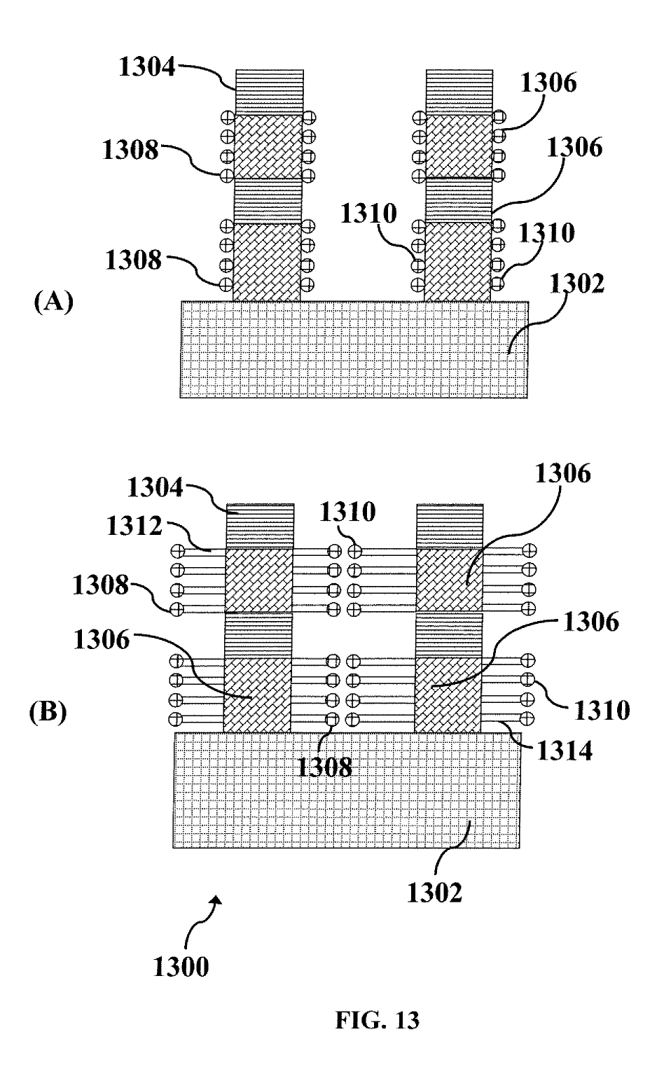

FIG. 13 illustrates a cross-sectional view of a diagram representing a plasmonic substrate device according to some embodiments of the present invention. Generally described, FIG. 13 illustrates a plasmonic substrate structure 1300 that comprises several elements (or components) that form the entire substrate. One-dimensional and two-dimensional arrays of nanostructures of multiple alternating layers of materials 1304 and 1306 are fabricated by employing one or a combination of the following processes but not limited to deep UV lithography, focused ion beam (FIB) milling, electron beam lithography, TEM lithography, wet or dry etching methods, and thin film deposition techniques.

The various elements of the plasmonic substrate structure 1300 can include varying types of components. For example, and as shown, plasmonic substrate structure 1300 can generally include a substrate platform 1302 on which the plasmonic substrate is developed, a first nanoparticle 1308 that is deposited, attached, or formed the surface of nanostructure region 1306 that are perpendicular to the platform 1302, and a second nanoparticle 1310 that is deposited, attached, or formed the surface of nanostructure region 1306 that are perpendicular to the platform 1302. Region 1304 on top of the region 1306 is selected or modified such that ensures there is no deposition, formation, or attachment of nanoparticles 1308 or 1310 on the surface of region 1304 (See FIG. 13A). The nanoparticles 1308 and 1310 are plasmonics-active and also act as catalysts for the growth of nanowires 1312 and 1314 laterally on regions 1306. The growth of the nanowires brings the plasmonics-active nanoparticles 1308 and 1310 closer to each other and this can enable the nano-scale gap between the plasmonic nanoparticles 1308 and 1310 to be precisely controlled.

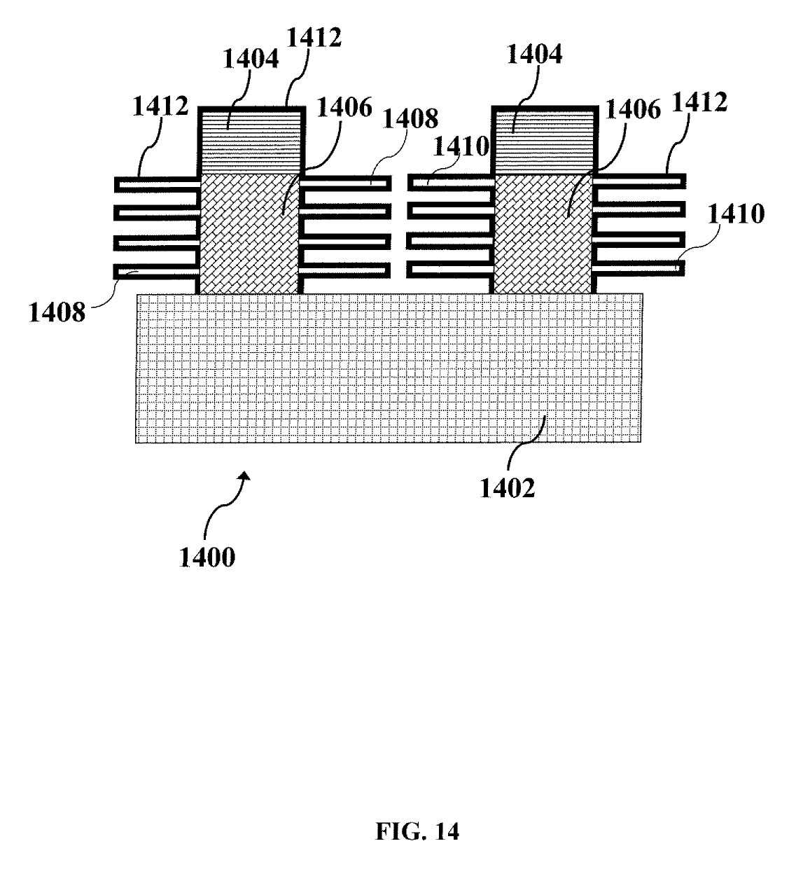

FIG. 14 illustrates a cross-sectional view of a diagram representing a plasmonic substrate device according to some embodiments of the present invention. One-dimensional and two-dimensional arrays of the nanostructures—with the nanostructure region 1404 on top of region 1406—are fabricated on the substrate 1402 by following one or a combination of the following processes but not limited to deep UV lithography, focused ion beam (FIB) milling, electron beam lithography, TEM lithography, wet etching, and dry etching.

The various elements of the plasmonic substrate structure 1400 can include varying types of components. For example, and as shown, plasmonic substrate structure 1400 can generally include a substrate platform 1402 on which the plasmonic substrate is developed, a first nanostructure 1408 that grows laterally from the surface of nanostructure region 1406 that are perpendicular to the platform 1402, a second nanostructure 1410 that grows laterally from the surface of nanostructure region 1406 that are perpendicular to the platform 1402, and a layer of plasmonics-active material 1412 coats the surface of the laterally grown regions 1408 and 1410. Region 1404 on top of the region 1406 ensures there is no growth of nanostructures 1408 and 1410 in the direction perpendicular to the platform 1402.

The nanostructures 1408, 1410 are not plasmonics-active and can be epitaxially grown by employing growth methods such as, that are not limited to, ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes etc.

The plasmonics-active thin film layer 1412 can take on a variety of shapes and include a variety of materials. Exemplary materials can include metallic or semiconductive materials that exhibit plasmonic properties. Specific material examples include but are not limited to Au, Ag, Cu, Pt, Pd, Ti, Cr, Zn, Al, Ni, Fe, V, W, Ru, Hf Zr, Ta, semiconducting materials, combinations of these materials, or a combination of these materials with metal oxides.

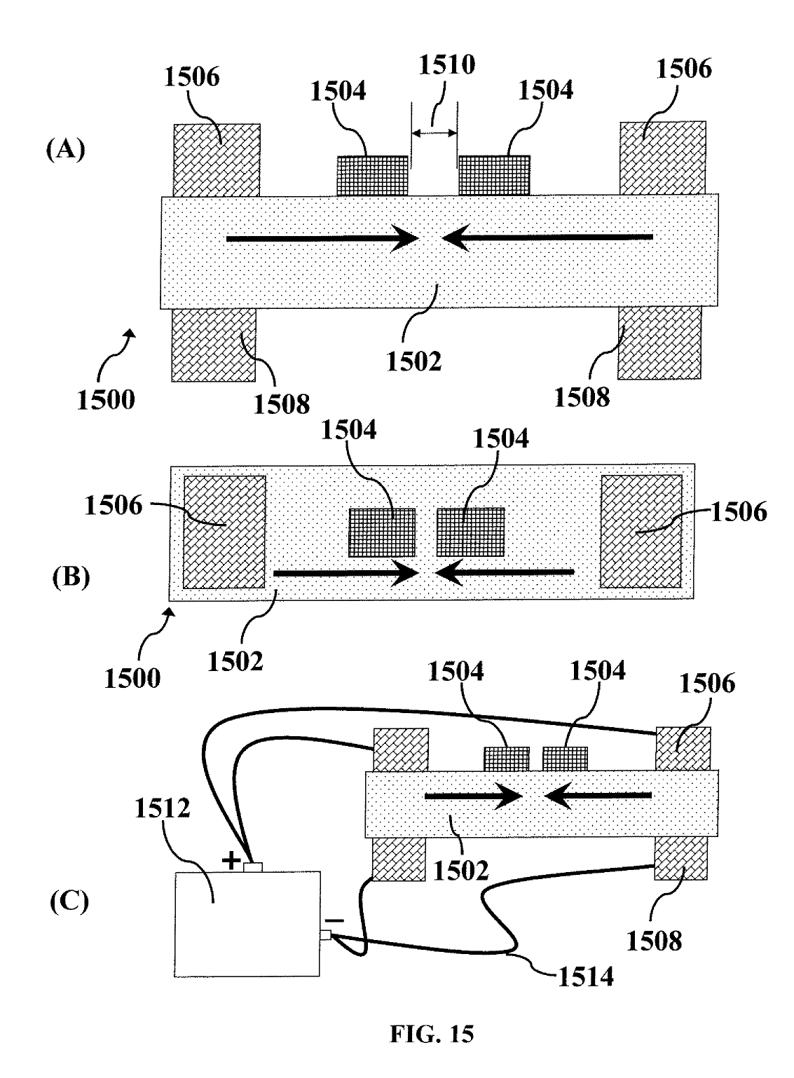

FIG. 15 illustrates cross-sectional views of a diagram representing how a plasmonic substrate structure 1500—consisting of an array of plasmonics-active nanostructures 1504 developed on an tunable substrate 1502—could be employed for controllably varying the nano-scale gap 1510 between the plasmonics-active nanostructures 1504. In one embodiment, the substrate 1502 is an electro-active substrate (see FIG. 15) such that the nano-scale spacing between neighboring nanostructures 1504 (that are attached to the substrate) could be tunable varied by the application of voltage or current. In another embodiment, the substrate 1502 is an electro-active polymer (see FIG. 15) such that the nano-scale spacing between neighboring nanostructures 1504 (that are attached to the substrate) could be tunable varied by the application of voltage or current to top and bottom electrodes (1506 and 1508 respectively) such that the regions of the electro-active polymer substrate between the electrodes 1506 and 1508 are compressed due to Maxwell's forces and cause the nanostructures 1504 to come closer to each other. Other embodiments of the tunable substrate 1502—such that the nano-scale spacing between nanostructures 1504 attached to the substrate could be tunable varied by the application of electric, magnetic, electromagnetic, or optical fields as well as voltage or current—include but are not limited to piezoelectric materials, ferroelectric polymers, dielectric elastomers, ionic polymer-metal composites, etc.

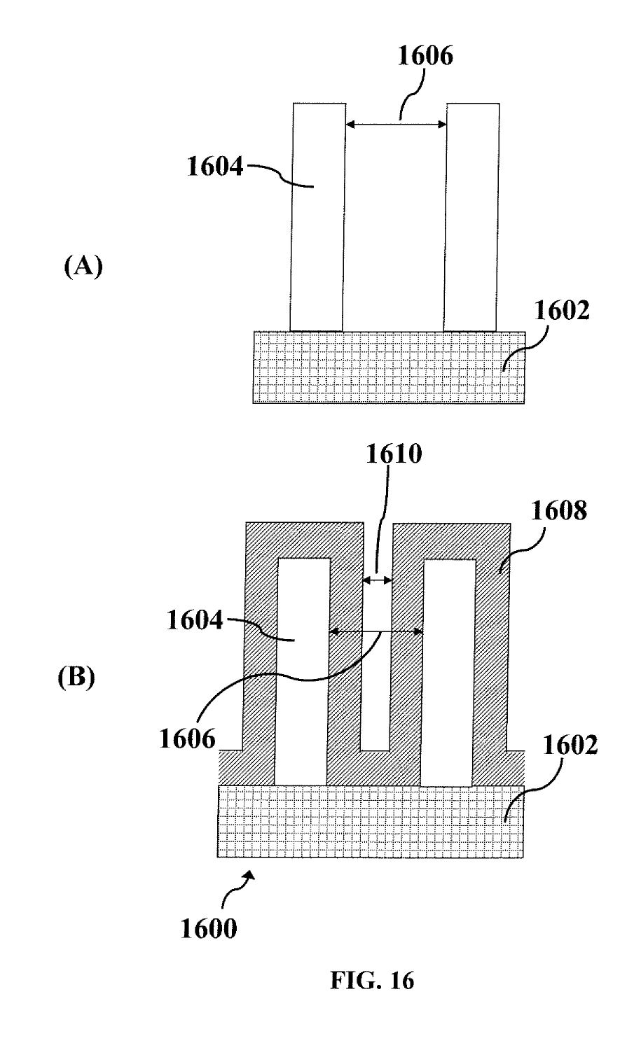

FIG. 16 illustrates cross-sectional views of a diagram representing how a plasmonic substrate structure 1600—consisting of an array of plasmonics-active nanostructures are developed by employing atomic layer deposition to tunably reduce the gap between neighboring plasmonics-active layer-coated nanostructures. Firstly, one-dimensional and two-dimensional arrays of the nanostructures 1604 are fabricated on the substrate 1602 by following one or a combination of the following processes but not limited to deep UV lithography, focused ion beam (FIB) milling, electron beam lithography, TEM lithography, wet etching, and dry etching. This is followed by atomic layer deposition of a plasmonics-active layer 1606 that controllably reduces the gap between the plasmonic layers 1610 to nano-scale dimensions (that include but are not limited to sub-10 nm gaps, sub-5 nm, or sub-2 nm dimensions) that provide the highest EM field enhancement between neighboring plasmonics-active metallic or metal-coated nanostructures.

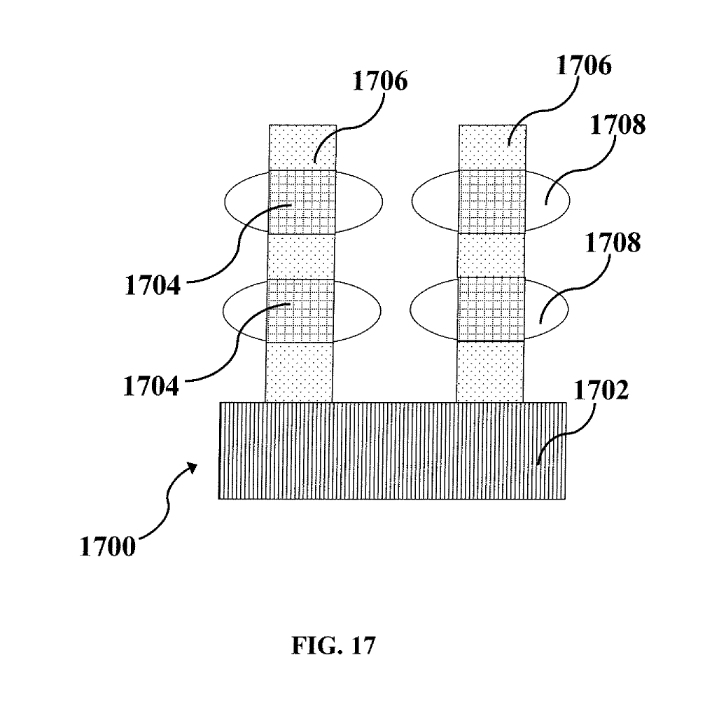

FIG. 17 illustrates a cross-sectional view of a diagram representing a plasmonic substrate device according to some embodiments of the present invention. Generally described, FIG. 17 illustrates a plasmonic substrate structure 1700 that comprises several elements (or components) that form the entire substrate. One-dimensional and two-dimensional arrays of nanostructures of multiple alternating layers of materials 1704 and 1706 are fabricated by employing one or a combination of the following processes but not limited to deep UV lithography, focused ion beam (FIB) milling, electron beam lithography, TEM lithography, wet or dry etching methods, and thin film deposition techniques.

The various elements of the plasmonic substrate structure 1700 can include varying types of components. For example, and as shown, plasmonic substrate structure 1700 can generally include a substrate platform 1702 on which the plasmonic substrate is developed, a first nanostructure—a one- or two-dimensional array of nanostructures containing a multilayer stack of regions 1704 and 1706, with regions 1704 and 1706 forming alternating layers of the stack—fabricated on the platform, and second nanostructure 1708 grown or selectively deposited, in the lateral direction, on the surface of nanostructure regions 1704 that are perpendicular to the platform 1702, the nanostructure 1708 being made of a plasmonics-active material.

The lateral nanostructures 1708 can be epitaxially grown or deposited on certain facets of nanostructure regions 1704 by employing growth methods such as—but not limited to—atomic layer deposition, ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes etc. By controlling the time and rate of the growth or deposition of the lateral nanostructures 1708, one can control the spacings between neighboring plasmonic nanostructures in the plasmonic substrate 1700. Hence, one can achieve nano-scale gaps (that could be smaller than 10 nm and if desirable even smaller than 5 nm) between neighboring plasmonics-active nanostructures that provide the highest enhancement of EM fields in the vicinity of these nanostructures.

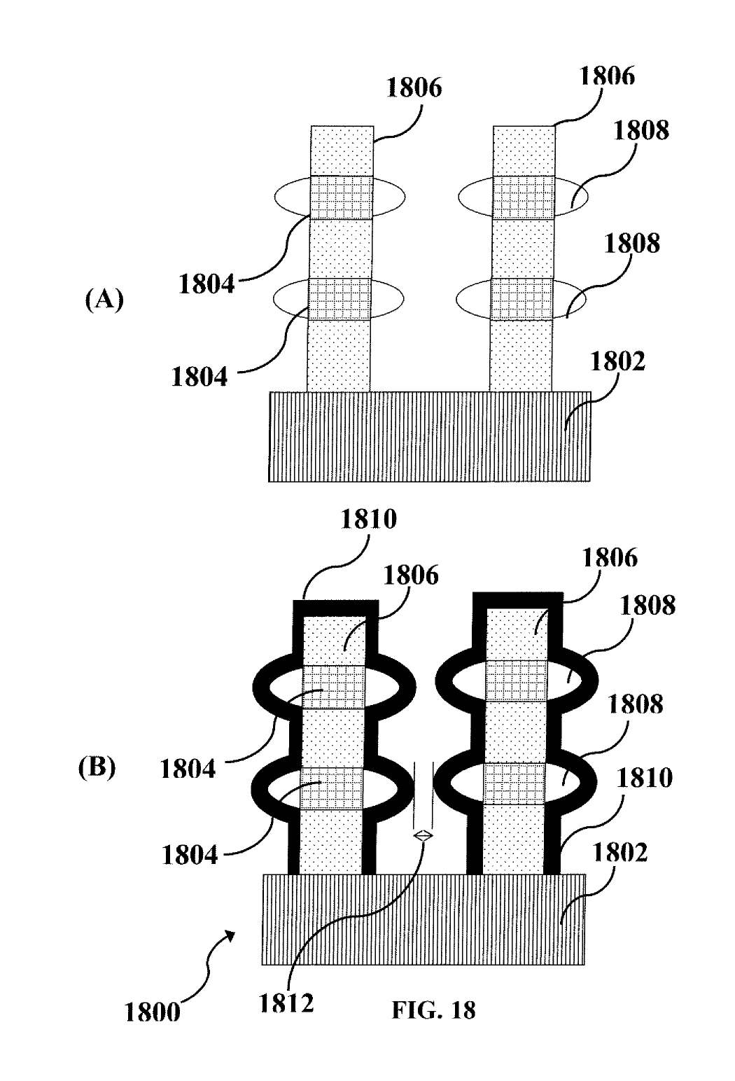

FIG. 18 illustrates a cross-sectional view of a diagram representing a plasmonic substrate device according to some embodiments of the present invention. Generally described, FIG. 18 illustrates a plasmonic substrate structure 1800 that comprises several elements (or components) that form the entire substrate. One-dimensional and two-dimensional arrays of nanostructures of multiple alternating layers of materials 1804 and 1806 are fabricated by employing one or a combination of the following processes but not limited to deep UV lithography, focused ion beam (FIB) milling, electron beam lithography, TEM lithography, wet or dry etching methods, and thin film deposition techniques.

The various elements of the plasmonic substrate structure 1800 can include varying types of components. For example, and as shown, plasmonic substrate structure 1800 can generally include a substrate platform 1802 on which the plasmonic substrate is developed, a first nanostructure—a one- or two-dimensional array of nanostructures containing a multilayer stack of regions 1804 and 1806, with regions 1804 and 1806 forming alternating layers of the stack—fabricated on the platform, second nanostructure 1808 grown or selectively deposited, in the lateral direction, on the surface of nanostructure regions 1804 that are perpendicular to the platform 1802—the nanostructure 1808 being made of a non plasmonics-active material, and a plasmonics-active layer 1810.

The lateral nanostructures 1808 can be epitaxially grown or deposited on certain facets of nanostructure regions 1804 by employing growth methods such as—but not limited to—atomic layer deposition, ultra high vacuum rapid thermal chemical vapor deposition, molecular beam epitaxy (MBE), thermal pulsed laser deposition, pulsed electron deposition, metal organic chemical vapor deposition (MOCVD), and hydrothermal processes etc. By controlling the time and rate of the growth or deposition of the lateral nanostructures 1808 as well as the thickness of the plasmonics-active layer, one can control the spacings between neighboring plasmonic nanostructures in the plasmonic substrate 1800. Hence, one can achieve nano-scale gaps (that could be smaller than 10 nm and if desirable even smaller than 5 nm) between neighboring plasmonics-active nanostructures that provide the highest enhancement of EM fields in the vicinity of these nano structures.

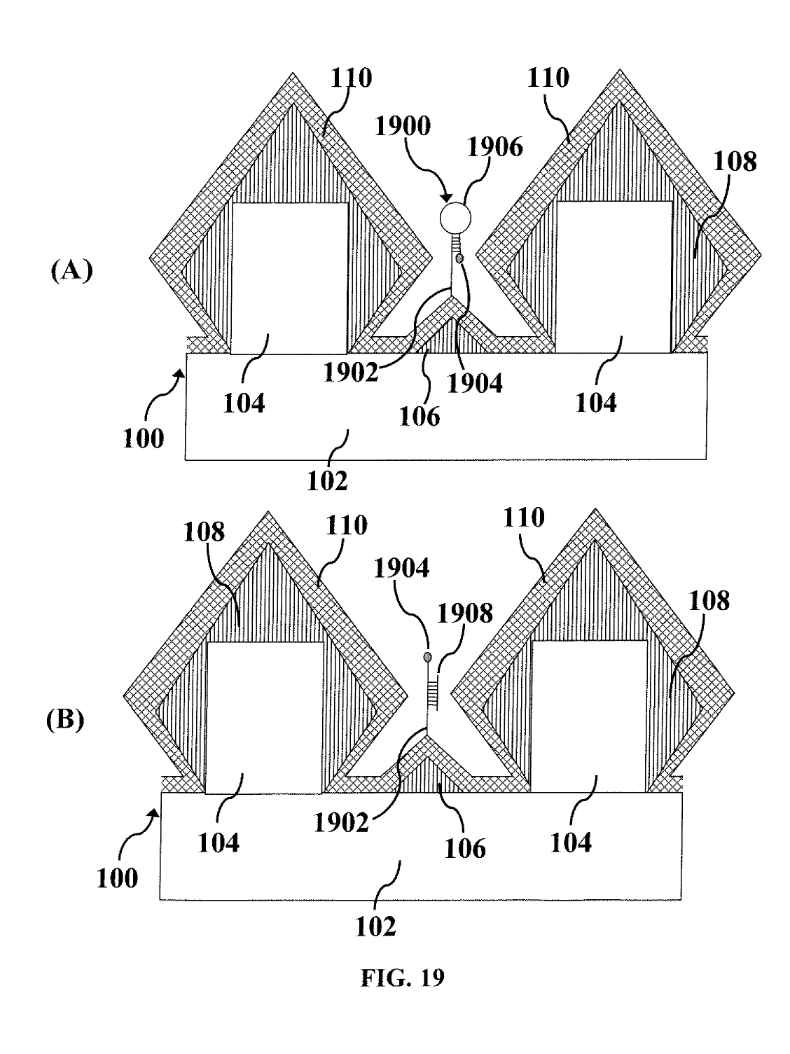

FIG. 19 illustrates a cross-sectional view of a diagram representing how a plasmonic substrate structure 100 could be employed for implementation of molecular sentinel-on-chip based detection of nucleic acids (DNAs and RNAs). Molecular sentinel 1900 is a hairpin DNA or RNA structure, with a SERS-active dye 1904 attached to one end of the sentinel, in which the hairpin structure 1906 opens up upon hybridization with complementary DNAs or RNAs 1908. Molecular sentinel probes have tremendous potential for multiplex nucleic acid detection. In order to apply the molecular sentinel-on-chip concept to the nanostructure substrate 100 for detection of nucleic acids, one end of the molecular sentinel hairpin structure 1902 is attached to the plasmonic layer coating 110 on top of the triangular region 106 such that the SERS signal is high when the hairpin structure of the molecular sentinel nucleic acid probe (DNA or RNA) is closed (see FIG. 19A)—as the SERS-active dye 1904 lies in the region between the tips of the nanostructures forming the plasmonic substrates 100. On hybridization to complementary DNA or RNA targets 1908, the hairpin structure 1906 opens up leading to the SERS-active dye 1904 moving away from the region between the tips of the nanostructures forming the plasmonic substrates 100 (See FIG. 19B) and therefore a decrease in the SERS signal.

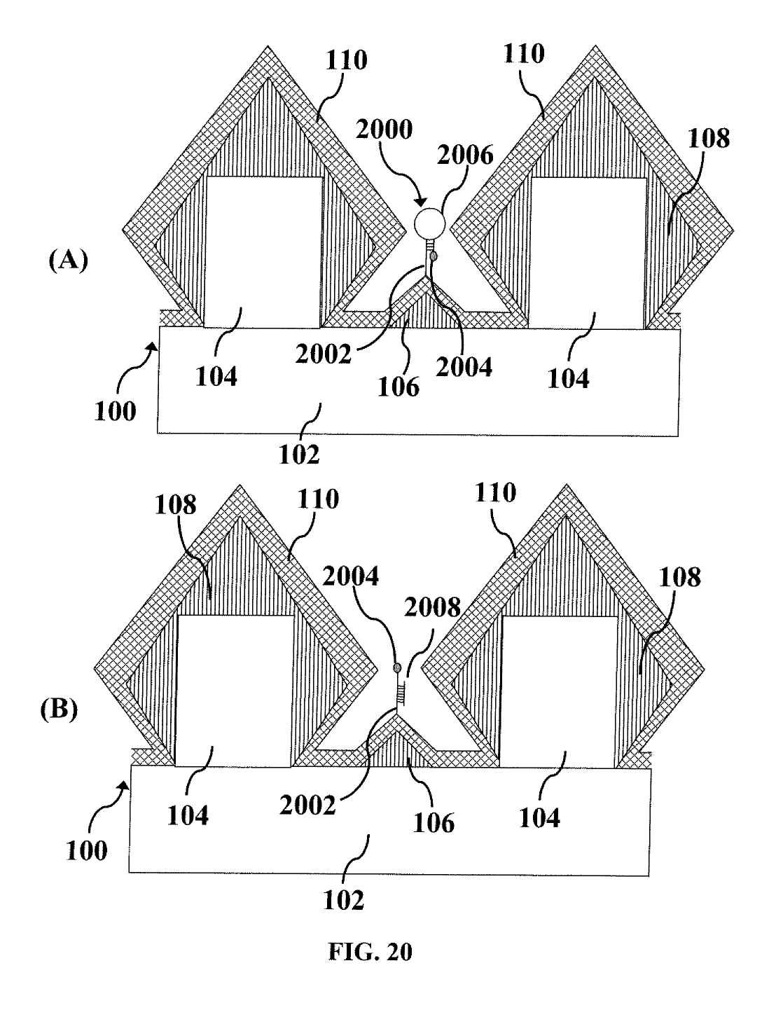

FIG. 20 illustrates a cross-sectional view of a diagram representing how a plasmonic substrate structure 100 could be employed for implementation of reverse molecular sentinel-on-chip based detection of nucleic acids (DNAs and RNAs). Molecular sentinel 2000 is a hairpin DNA or RNA structure, with a SERS-active dye 2004 attached to one end of the sentinel, in which the hairpin structure 2006 opens up upon hybridization with complementary DNAs or RNAs 2008. In order to apply the molecular sentinel-on-chip concept to the nanostructure substrate 100 for detection of nucleic acids, one end of the molecular sentinel hairpin structure 2002 is attached to the plasmonic layer coating 110 on top of the triangular region 106 such that the SERS signal is low when the hairpin structure of the molecular sentinel nucleic acid probe (DNA or RNA) is closed (see FIG. 20A)—as the SERS-active dye 2004 lies outside the region between the tips of the nanostructures forming the plasmonic substrates 100. On hybridization to complementary DNA or RNA targets 2008, the hairpin structure 2006 opens up leading to the SERS-active dye 2004 moving away into the region between the tips of the nanostructures forming the plasmonic substrates 100 (see FIG. 20B) and therefore a increase in the SERS signal As an increase in the SERS signal upon hybridization of the target DNA and RNA molecules is the opposite of the case of a regular molecular sentinel-based SERS detection of DNAs and RNAs, we term this reverse molecular sentinel concept.

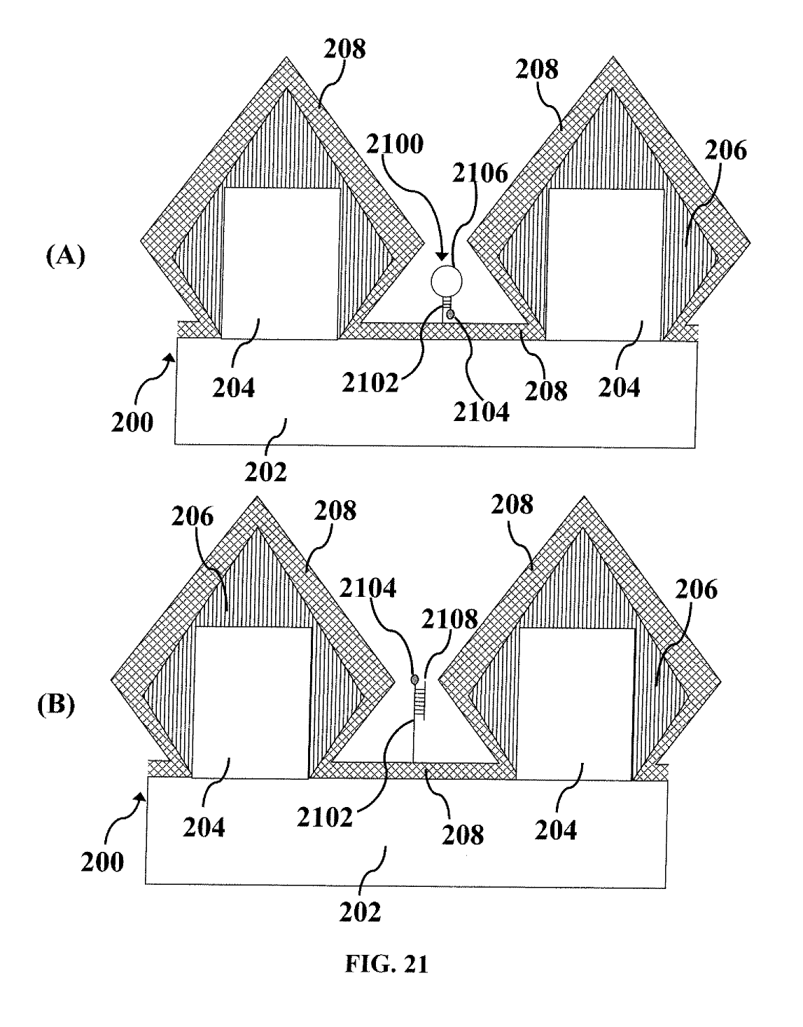

FIG. 21 illustrates a cross-sectional view of a diagram representing how a plasmonic substrate structure 200 could be employed for implementation of reverse molecular sentinel-on-chip based detection of nucleic acids (DNAs and RNAs). Molecular sentinel 2100 is a hairpin DNA or RNA structure, with a SERS-active dye 2104 attached to one end of the sentinel, in which the hairpin structure 2106 opens up upon hybridization with complementary DNAs or RNAs 2108. In order to apply the molecular sentinel-on-chip concept to the nanostructure substrate 200 for detection of nucleic acids, one end of the molecular sentinel hairpin structure 2002 is attached to the plasmonic layer coating 208 on top of the bottom substrate region 202 such that the SERS signal is low when the hairpin structure of the molecular sentinel nucleic acid probe (DNA or RNA) is closed (see FIG. 21A)—as the SERS-active dye 2104 lies outside the region between the tips of the nanostructures forming the plasmonic substrates 100. On hybridization to complementary DNA or RNA targets 2108, the hairpin structure 2106 opens up leading to the SERS-active dye 2104 moving into the region between the tips of the nanostructures forming the plasmonic substrates 200 (see FIG. 21B) and therefore a increase in the SERS signal.

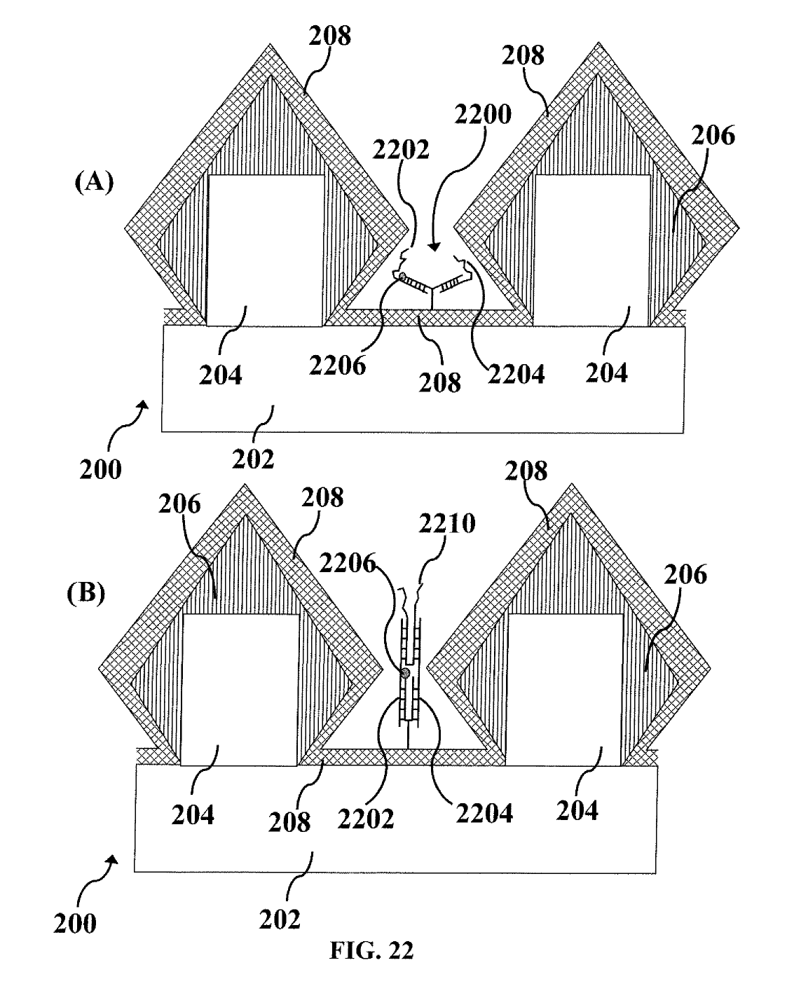

FIG. 22 illustrates a cross-sectional view of a diagram representing how a plasmonic substrate structure 200 could be employed for implementation of molecular tweezer based detection of nucleic acids (DNAs and RNAs). A molecular tweezer 2200 is a Y-shaped DNA or RNA structure, with a SERS-active dye 2206 attached to one end of the Y-shaped structure and parts of DNA segments 2202 and 2204 attached to the two arms of the Y-shaped molecular tweezer. In order to apply the molecular tweezer structure for detection of nucleic acids, the bottom of the Y-shaped structure of the molecular tweezer structure is attached to the plasmonic layer coating 208 on top of the bottom substrate region 202. The SERS signal is low when the Y-shaped molecular tweezer is open (see FIG. 22A). On hybridization to complementary DNA or RNA targets 2208 to the DNA segments 2202 and 2204 attached to the two arms of the nucleic acid probe (DNA or RNA), the Y-shaped molecular tweezer structure closes and causes the SERS-active dye 2206 to come into the region between the tips of the nanostructures forming the plasmonic substrates 200 (see FIG. 22B) and therefore a increase in the SERS signal.

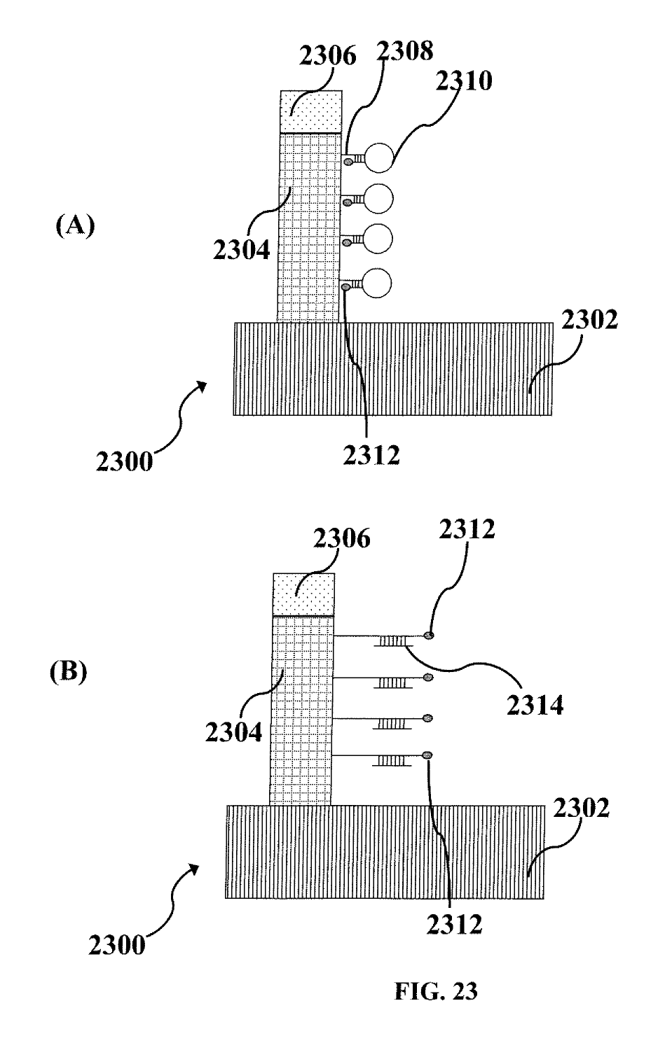

FIG. 23 illustrates a cross-sectional view of a diagram representing how a plasmonic substrate structure 2300 consisting of an array of plasmonics-active nanostructures 2304 could be employed for implementation of molecular sentinel-on-chip based detection of nucleic acids (DNAs and RNAs). The layer 2306 deposited on top of the nanostructure 2304 prevents attachment of the molecular sentinel on the top surface of the nanostructure 2304. In the molecular sentinel DNA or RNA structure, a SERS-active dye 2312 is attached to one end of the sentinel and the hairpin structure 2310 opens up upon hybridization with complementary DNAs or RNAs 2314. In order to apply the molecular sentinel-on-chip concept to the nanostructure substrate 2300 for detection of nucleic acids, one end of the molecular sentinel hairpin structure 2308 is attached to the plasmonics-active nanostructure 2304 such that the SERS signal is high when the hairpin structure of the molecular sentinel nucleic acid probe (DNA or RNA) is closed (see FIG. 23A)—as the SERS-active dye 2312 lies in the vicinity (sub-5 nm region) of the plasmonics-active nanostructure 2304. On hybridization to complementary DNA or RNA targets 2314, the hairpin structure 2310 opens up leading to the SERS-active dye 2314 moving away from the nanostructures forming the plasmonic substrates 2300 (see FIG. 23B) and therefore a decrease in the SERS signal. It has to be noted that the different plasmonic active nanostructures 2304 present in the array of nanostructures (in the plasmonic substrate 2300) are sufficiently far from each other such that the SERS-active dye 2312 is sufficiently away from (at least a distance greater than 10 nanometers) the neighboring plasmonic nanostructure 2304 when the hairpin structure 2310 opens up upon hybridization with complementary DNAs or RNAs 2314.

The nanostructure 2304 can be made from a variety of plasmonics materials. Exemplary materials can include metallic, dielectric, or semiconductive materials. Specific material examples include but are not limited to Au, Ag, Cu, Pt, Pd, Ti, Cr, Zn, Al, Ni, Fe, V, W, Ru, Hf Zr, Ta, metal oxides, other dielectric and semiconductor materials, or combinations of these materials. The combination of these materials could be achieved as a metal-coated dielectric or semiconducting nanostructure, a multilayer stack (i.e. multiple layers of the different materials described above forming a composite material) or with a nano-composite material (with nanoparticles or nano-crystals of the different materials embedded in other materials).

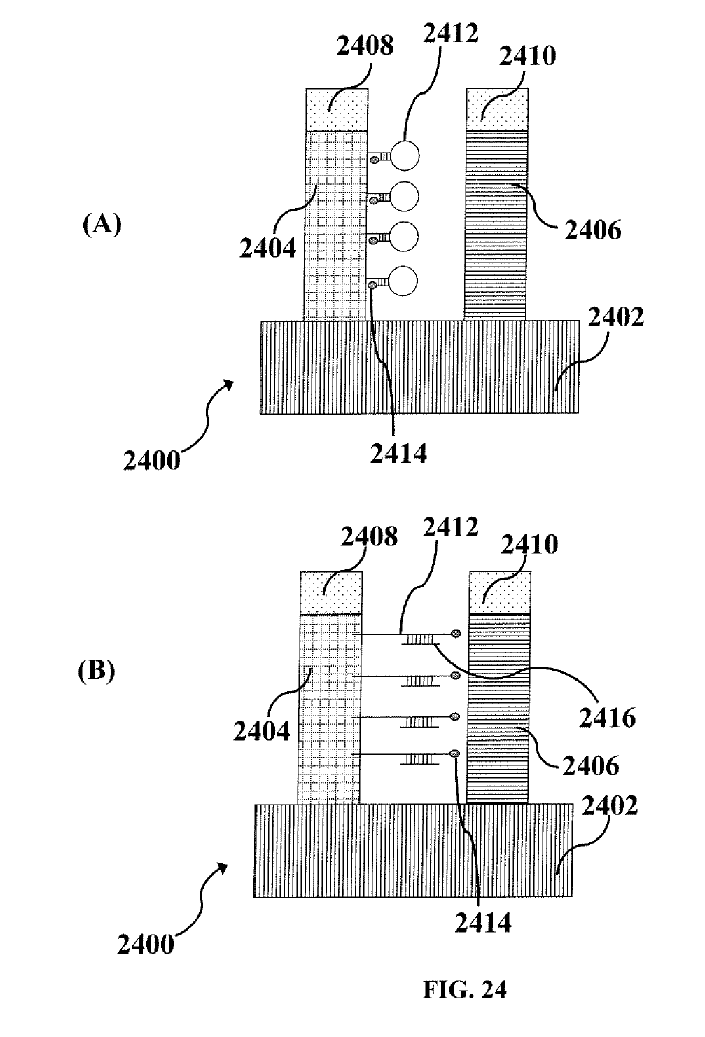

FIG. 24 illustrates a cross-sectional view of a diagram representing how a plasmonic substrate structure 2400 consisting of an array of plasmonics-active nanostructures 2406 and non plasmonic structures 2404—such that the nanostructures 2404 and 2406 are arranged adjacent to each other in the one- or two-dimensional array of nanostructures—could be employed for implementation of reverse molecular sentinel-on-chip based detection of nucleic acids (DNAs and RNAs). The layers 2408 and 2410 deposited on top of the nanostructures 2404 and 2406 respectively prevent attachment of the molecular sentinel on the top surface of the nanostructures 2404 and 2406 respectively. In the molecular sentinel DNA or RNA structure, a SERS-active dye 2414 is attached to one end of the sentinel and the hairpin structure 2412 opens up upon hybridization with complementary DNAs or RNAs 2416. In order to apply the molecular sentinel-on-chip concept to the nanostructure substrate 2400 for detection of nucleic acids, one end of the molecular sentinel hairpin structure is attached to the non plasmonics-active nanostructure 2404 such that the SERS signal is low when the hairpin structure of the molecular sentinel nucleic acid probe (DNA or RNA) is closed (See FIG. 24A)—as the SERS-active dye 2414 lies in the vicinity of a non plasmonics-active nanostructure 2404. On hybridization to complementary DNA or RNA targets 2416, the hairpin structure 2412 opens up leading to the SERS-active dye 2314 moving towards the plasmonics-active nanostructures 2406 on the plasmonic substrates 2400 (see FIG. 24B) and therefore an increase in the SERS signal. It has to be noted that the plasmonic-active nanostructures 2406 present in the array of nanostructures (in the plasmonic substrate 2400) are sufficiently close to the non plasmonic structures 2404 such that SERS-active dye 2414 is sufficiently close to (within 10 nanometers) the neighboring plasmonic nanostructure 2406 when the hairpin structure 2412 opens up upon hybridization with complementary DNAs or RNAs 2416.

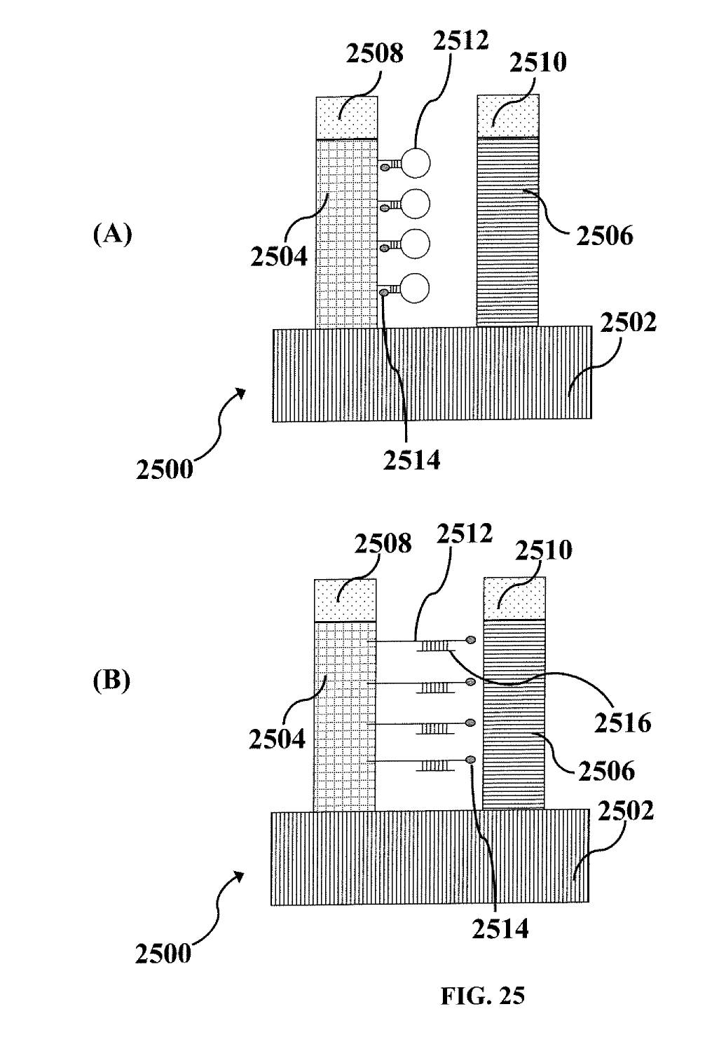

FIG. 25 illustrates a cross-sectional view of a diagram representing how a plasmonic substrate structure 2500 consisting of an array of plasmonics-active nanostructures 2506 and non plasmonic structures 2504—such that the nanostructures 2504 and 2506 are arranged adjacent to each other in the one- or two-dimensional array of nanostructures—could be employed for implementation of reverse molecular sentinel-on-chip based detection of nucleic acids (DNAs and RNAs). In one embodiment, the substrate 2502 is an electro-active substrate such that the nano-scale spacing between 2504 and 2506 (that are attached to the substrate) could be tunable varied by the application of voltage or current. The layers 2508 and 2510 deposited on top of the nanostructures 2504 and 2506 respectively prevent attachment of the molecular sentinel on the top surface of the nanostructures 2504 and 2506 respectively. In the molecular sentinel DNA or RNA structure, a SERS-active dye 2514 is attached to one end of the sentinel and the hairpin structure 2512 opens up upon hybridization with complementary DNAs or RNAs 2516. In order to apply the molecular sentinel-on-chip concept to the nanostructure substrate 2500 for detection of nucleic acids, one end of the molecular sentinel hairpin structure is attached to the non plasmonics-active nanostructure 2504 such that the SERS signal is low when the hairpin structure of the molecular sentinel nucleic acid probe (DNA or RNA) is closed (See FIG. 25A)—as the SERS-active dye 2514 lies in the vicinity of a non plasmonics-active nanostructure 2504. Before hybridization of the complementary DNA or RNA to the molecular sentinel, the plasmonic-active nanostructure 2506 is moved sufficiently far away from 2504 such that there is enough space between the nanostructures for the complementary target DNA or RNA to hybridize with the molecular sentinel DNA or RNA. After the hybridization is complete the nanostructure 2506 is brought back to its original position or sufficiently close to the SERS-active dye 2514. On hybridization to complementary DNA or RNA targets 2516, the hairpin structure 2512 opens up leading to the SERS-active dye 2514 moving towards the plasmonics-active nanostructures 2506 on the plasmonic substrates 2500 (See FIG. 25B) and therefore an increase in the SERS signal. Other embodiments of the tunable substrate 2502—such that the nano-scale spacing between nanostructures 2504 and 2506 attached to the substrate could be tunable varied by the application of electric field, voltage, or current—include but are not limited to piezoelectric materials, ferroelectric polymers, dielectric elastomers, ionic polymer-metal composites, etc.

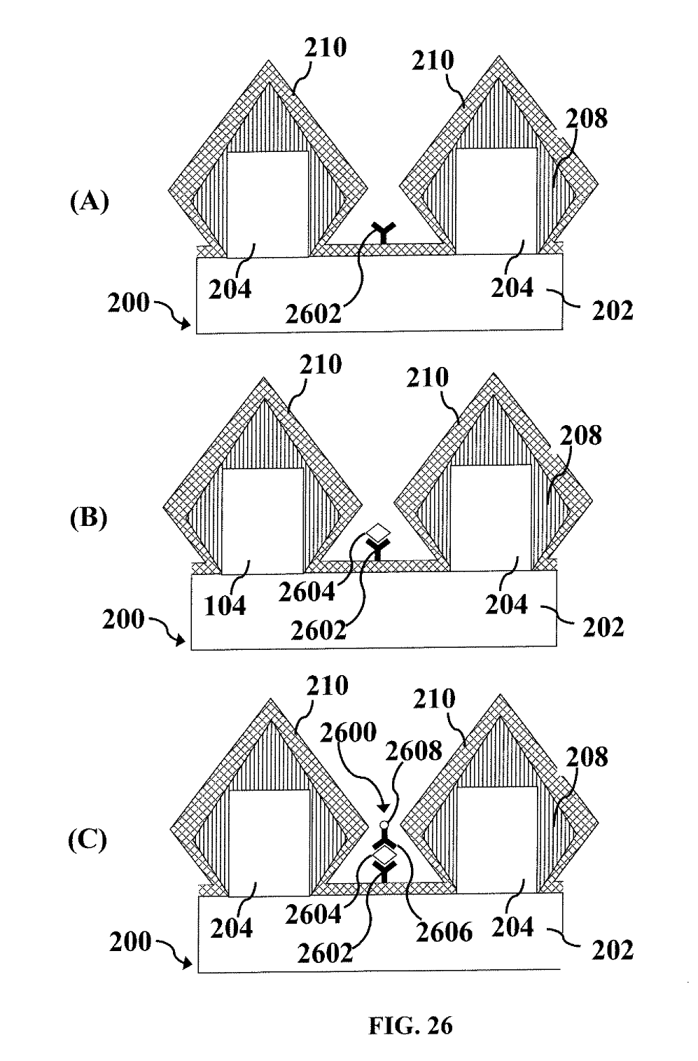

FIG. 26 illustrates cross-sectional views of a diagram representing how a plasmonic substrate structure 200 consisting of an array of plasmonics-active nanostructures could be employed for SERS-based detection of antigens. First an unlabeled antibody 2602 is attached to the plasmonic-layer surface above the substrate platform 202 (see FIG. 26A). This is followed by specific detection of antigen 2604 by binding of the antigen to the antibody (See FIG. 26). In order to probe the antigen, a labeled antibody—labeled with a SERS-dye 2608—binds with the antigen to create a sandwich structure 2600. On formation of the sandwich structure, if the SERS-active dye 2608 lies in the region between the tips of the nanostructures forming the plasmonic substrates 200 (see FIG. 26C), there is a strong SERS signal from the SERS-dye 2608.

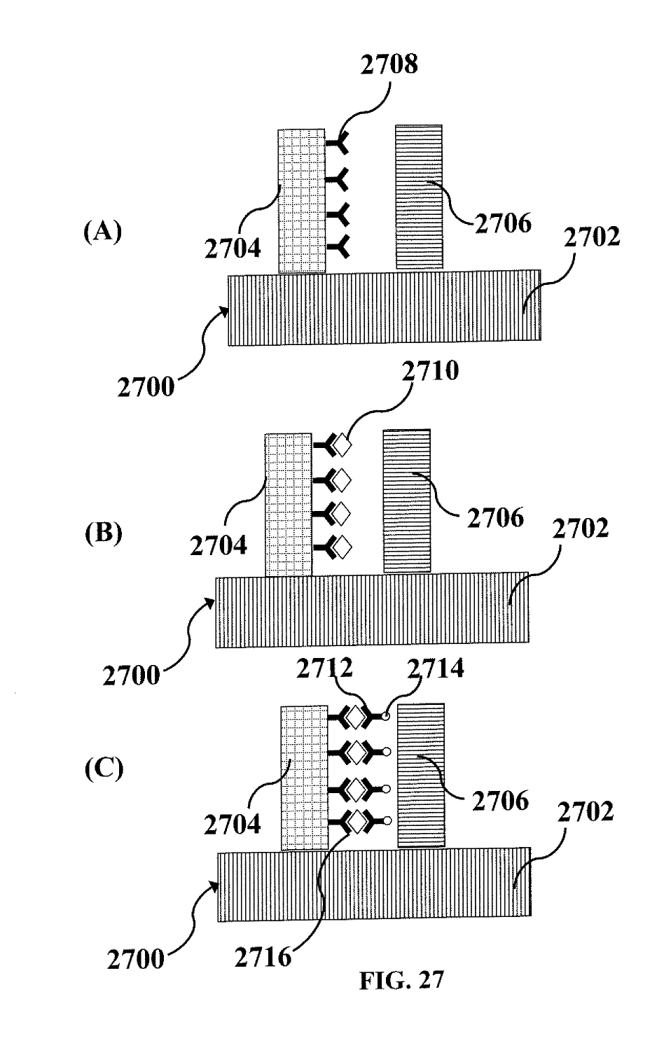

FIG. 27 illustrates cross-sectional views of a diagram representing how a plasmonic substrate structure 2700 consisting of an array of plasmonics-active nanostructures could be employed for SERS-based detection of antigens. First an unlabeled antibody 2708 is attached to the sidewalls of the plasmonic nanostructures 2704 (see FIG. 27A). This is followed by specific detection of antigen 2710 by binding of the antigen to the antibody (see FIG. 27B). In order to probe the antigen, a labeled antibody—labeled with a SERS-dye 2712—binds with the antigen to create a sandwich structure 2716. On formation of the sandwich structure, the SERS-active dye 2714 lies in the vicinity of the nanostructure 2706 thereby leading to a strong SERS signal from the SERS-dye 2712.

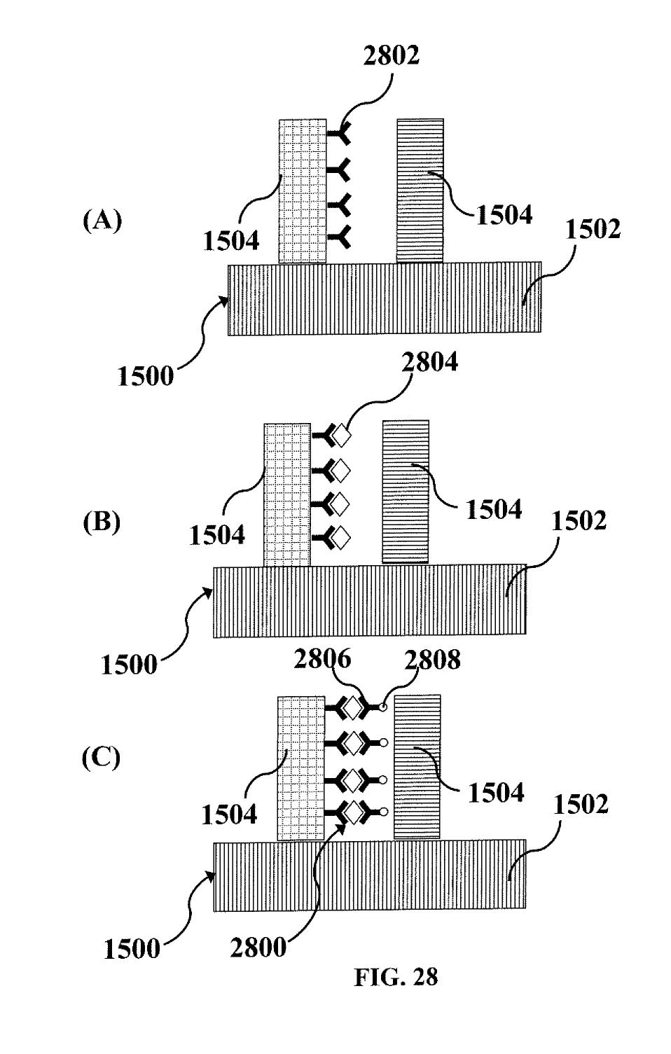

FIG. 28 illustrates cross-sectional views of a diagram representing how a plasmonic substrate structure 1500—consisting of an array of plasmonics-active nanostructures 1504 developed on an tunable substrate 1502—could be employed for SERS-based detection of antigens. First an unlabeled antibody 2802 is attached to the sidewalls of the plasmonic nanostructures 1504 (see FIG. 28A). This is followed by specific detection of antigen 2804 by binding of the antigen to the antibody (see FIG. 28B). In order to probe the antigen, a labeled antibody 2806—labeled with a SERS-dye 2808—binds with the antigen to create a sandwich structure 2800. Before formation of the sandwich structure, the plasmonic-active nanostructure 1504 is moved sufficiently far away from the neighboring plasmonic-active nanostructure 1504 such that there is enough space between the nanostructures for the antigen and antibody to bind. After the formation of the sandwich structure is complete the nanostructures 1504 are brought back to their original position or sufficiently close to the SERS-active dye 2808, thereby leading to a strong SERS signal from the SERS-dye 2808.

In one embodiment, the substrate 1502 is an electro-active substrate such that the nano-scale spacing between neighboring nanostructures 1504 (that are attached to the substrate) could be tunable varied by the application of voltage or current. Other embodiments of the tunable substrate 1502—such that the nano-scale spacing between nanostructures 1504 attached to the substrate could be tunable varied by the application of electric field, voltage, or current—include but are not limited to piezoelectric materials, ferroelectric polymers, dielectric elastomers, ionic polymer-metal composites, etc.

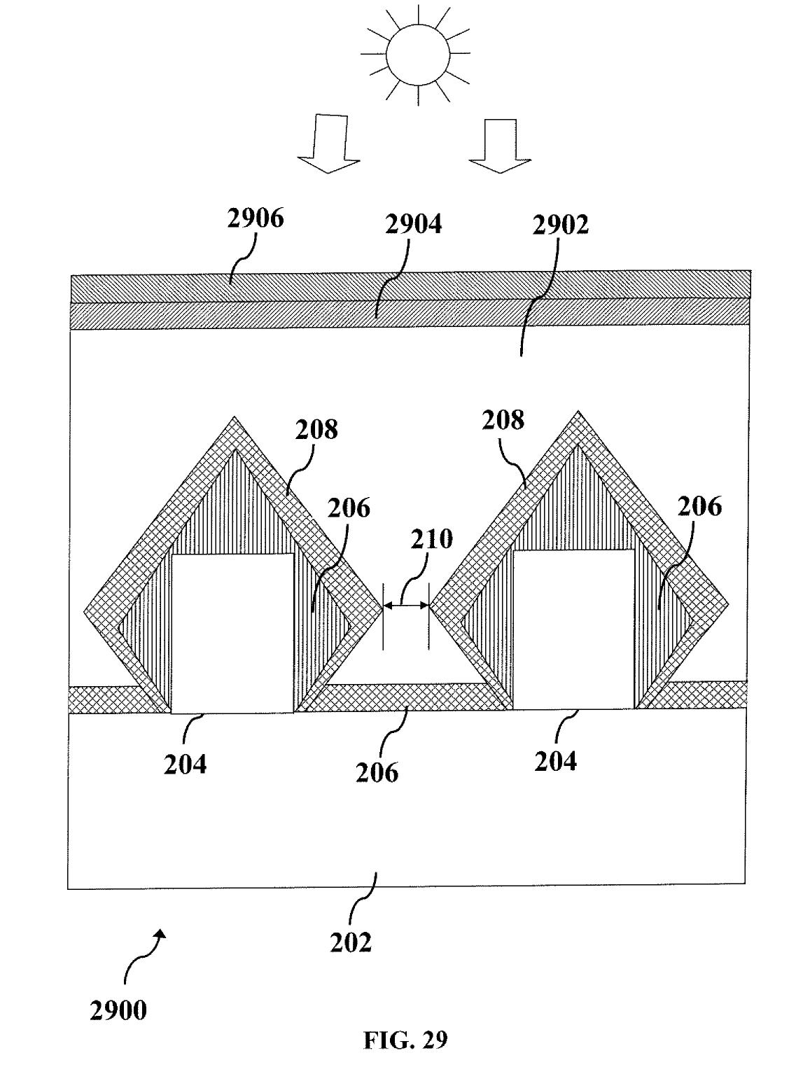

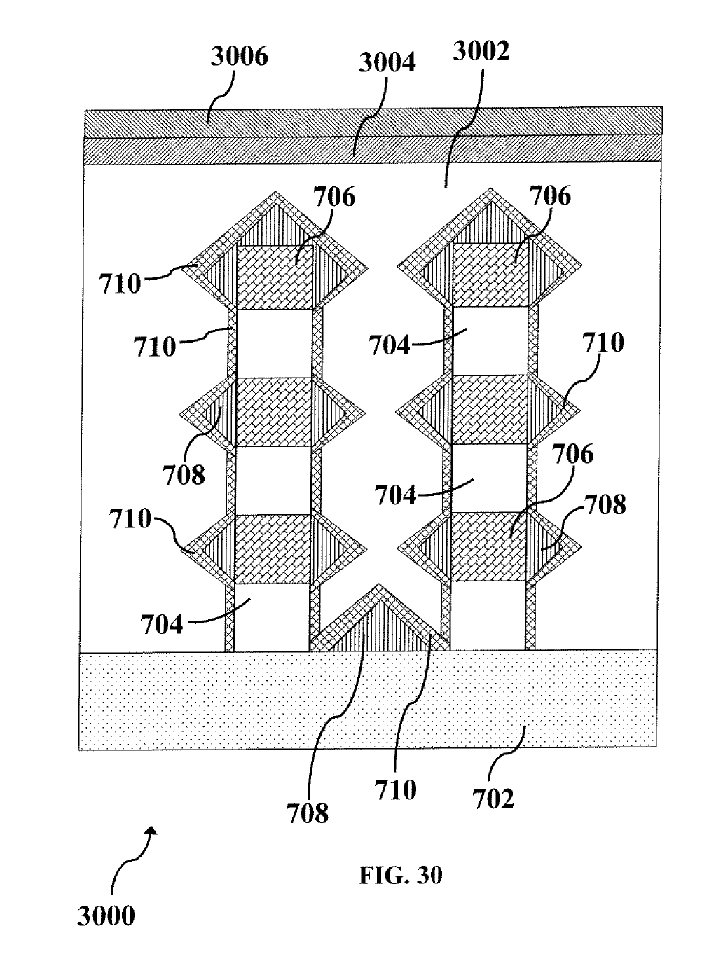

FIGS. 29 and 30 illustrate cross-sectional views of a diagram representing how plasmonic substrate structures 2900 and 3000—that consist of plasmonics-active nanostructure substrates 200 and 700 respectively as the plasmonics-enhancing regions—could be employed for the development of plasmon-enhanced solar cells. In FIG. 29, 2902, 2904, and 2906 are active layers, top transparent conductive layer, and the antireflection coatings respectively. In FIG. 30, 3002, 3004, and 3006 are active layers, top transparent conductive layer, and the antireflection coatings respectively. In one embodiment of the invention, the plasmonic substrates 200 and 700 in FIGS. 29 and 30 respectively can function for both plasmonic enhancement (enhancement of EM fields and enhanced light absorption, scattering, and trapping) inside the active region of the solar cell and as a back electrode. Various other embodiments, of employing the different kinds of plasmonic substrates described in this invention, for the development of plasmon-enhanced solar cells are possible.

Other system sensing embodiments are also possible and contemplated with the present invention. Indeed, the sensing devices of the present invention can be utilized to sense and obtain a variety of from a variety of media. For example, sensing devices according to the present invention may be utilized as temperature sensors, chemical sensors, biological sensors, and biomedical sensors. Other media types in which the plasmonic substrates of the present invention can be deployed include polymeric films, ambient air environments, partial or full liquid environments, and ventilation ducts.

Moreover, different metallic (or a combination of metallic and semiconducting or metallic and dielectric materials) materials as well as alloys (or combination of more than one metallic material) could be employed to form the plasmonic substrates described in this invention to engineer the plasmon resonance wavelength to be in the desired region of interest. For example, for metallic thin films (or a combination of metallic and semiconducting or metallic and dielectric materials), plasmon resonance related dips can be engineered by selecting appropriate film thickness and material. As another example, for semiconducting films and nanostructures, the geometry as well as the combination of materials employed could be engineered to provide a desired absorption edge (band edge) in transmission spectrum of the material. The engineering of the plasmon resonance wavelengths as well as the absorption edge (band edge) can be employed to match the spectral regimes of the light sources and detectors employed in the sensing.

The embodiments of the present invention are not limited to the particular formulations, process steps, and materials disclosed herein as such formulations, process steps, and materials may vary somewhat. Moreover, the terminology employed herein is used for the purpose of describing exemplary embodiments only and the terminology is not intended to be limiting since the scope of the various embodiments of the present invention will be limited only by the appended claims and equivalents thereof.

Therefore, while embodiments of the invention are described with reference to exemplary embodiments, those skilled in the art will understand that variations and modifications can be effected within the scope of the invention as defined in the appended claims. Accordingly, the scope of the various embodiments of the present invention should not be limited to the above discussed embodiments, and should only be defined by the following claims and all equivalents.

We claim:

1. A plasmonic nanostructure substrate device to sense environmental information, the device comprising:
a one-dimensional or two-dimensional array of plasmonics nanostructures on a wafer scale having nano-scale gap dimensions between neighboring nanostructures such that the highest possible plasmonic enhancement of electromagnetic fields in the vicinity of the plasmonics-active nanostructures is achieved,
wherein the plasmonic nanostructures are configured to have at least one dimension substantially smaller than the wavelength of the incident radiation such that plasmon resonances associated with the plasmonic nanostructures or the array of the plasmonic nanostructures correspond to the wavelength of the incident radiation; and
an environmentally sensitive film layer disposed on the surface of the plasmonic nanostructures such that the environmentally sensitive region changes optical properties in response to the changes in refractive index, temperature, surrounding media, as well as binding of different molecules to the environmentally sensitive film layer, wherein
the environmental sensing region is configured to have a thickness substantially smaller than the wavelength of the incident radiation and the thickness is small enough that the incident radiation can interact with the underlying plasmonic substrate and excite plasmon resonance in the plasmonic substrate at certain wavelengths of the incident radiation.

2. The device of claim 1 having two nanostructure arrays, wherein the first nanostructure array is developed on a planar substrate and a second nanostructure array is formed on the vertical faces, the first nanostructure array being in a direction parallel to the substrate.

3. The device of claim 2, wherein the formation of the second nanostructure array occurs due to epitaxial growth or deposition of plasmonic materials.

4. The device of claim 3, wherein the formation of the second nanostructure array occurs due to epitaxial growth or deposition epitaxial growth of non-plasmonic materials such that the first and second nanostructures are further coated with a layer of the plasmonic material.

5. The device of claim 3, wherein the formation of the second nanostructure array is in the lateral direction and reduces the nano-scale gaps between the adjacent nanostructures in the plasmonic substrate.

6. The device of claim 1, the gaps between adjacent plasmonic nanostructures in the substrate are smaller than 20 nm.

7. The device of claim 1, the gaps between adjacent plasmonic nanostructures in the substrate are smaller than 10 nm.

8. The device of claim 1, the gaps between adjacent plasmonic nanostructures in the substrate being smaller than 5 nm.

9. The device of claim 5, wherein the nano-scale gaps between adjacent plasmonic nanostructures are variably controlled by developing the nanostructures on a substrate that is tunably moved such that the nanostructures attached to the substrate are brought closer or separated in a controllable manner.

10. The device of claim 5, wherein the nano-scale gaps between adjacent plasmonic nanostructures are variably controlled by developing the nanostructures on an electro-active substrate and applying electric field to actively move the substrate and the nanostructures developed on the substrates.

11. The device of claim 5, wherein the nano-scale gaps between adjacent plasmonic nanostructures are variably controlled by moving the substrate on which the nanostructures are developed in an active manner by the application of at least one of electromagnetic, optical, magnetic, or thermal fields.

12. The device of claim 5, wherein the nano-scale gaps between adjacent plasmonic nanostructures are variably controlled to sense nucleic acids, such that the gaps are larger before the detection of target molecules for the target molecules to reach the sensing regions and the gaps are controllably reduced after the attachment of the target molecules to the probe molecules on the sensing region.

13. The device of claim 5, wherein the nano-scale gaps between adjacent plasmonic nanostructures are variably controlled for sensing antigens and antibodies, such that the gaps are larger before the detection of target molecules for the target molecules to reach the sensing regions and the gaps are controllably reduced after the attachment of the target molecules to the probe molecules on the sensing region.

14. A plasmonic nanostructure substrate device for plasmonically enhancing the properties of active devices taken from the group consisting of solar cells, photodetectors and light sources, the device comprising:
a one-dimensional or two-dimensional array of plasmonics nanostructures having nano-scale gap dimensions between neighboring nanostructures such that the highest possible plasmonic enhancement of electromagnetic fields in the vicinity of the plasmonics-active nanostructures is achieved,
wherein the plasmonic nanostructures are configured to have at least one dimension substantially smaller than the wavelength of the incident radiation such that plasmon resonances associated with the plasmonic nanostructures or the array of the plasmonic nanostructures correspond to the wavelength of the incident radiation; and
an active region where the plasmonic enhancement of the electromagnetic fields and enhanced absorption, scattering, and trapping of light of certain wavelengths, lead to higher efficiencies associated with the device.

15. A method to fabricate a plasmonic nanostructure substrate device to sense environmental information, the method comprising:
providing a first one-dimensional or two-dimensional array of nanostructures using the conventional nanolithography processes;
providing a second nanostructure formed laterally from the vertical surfaces of the first nanostructures; and
providing a coating of a plasmonics-active layer on the first and second nanostructures if they are not made of plasmonic material.

16. The method of claim 15, further comprising providing the second nanostructure, wherein the formation of the second nanostructure occurs due to epitaxial growth.

17. The method of claim 15, further comprising providing the second nanostructure, wherein the formation of the second nanostructure occurs due to epitaxial growth of silicon germanium on certain facets of silicon nanostructures fabricated on the substrate, such that the nanostructures are further coated with a plasmonic material.

18. The method of claim 15, further comprising providing the second nanostructure, wherein the formation of the second nanostructure occurs due to epitaxial growth in the presence of catalyst nanoparticles and nanoparticles on the vertical surfaces of the first nanostructure array.

19. The method of claim 18, further comprising providing the second nanostructure, wherein the formation of the second nanostructure occurs due to material deposition or evaporation.

20. The method of claim 18, further comprising providing the second nanostructure, wherein the formation of the second nanostructure occurs due to atomic layer deposition.
